(19) United States
(12) Patent Application Publication
(10) Pub. No.: US 2025/0372168 A1
(43) Pub. Date: Dec. 4, 2025

(54) MEMORY DEVICE INCLUDING CONDUCTIVE CONTACTS IN TREATED TIERS

(71) Applicant: Micron Technology, Inc., Boise, ID (US)

(72) Inventors: Sidhartha Gupta, Boise, ID (US); Matthew J. King, Boise, ID (US); Richard J. Hill, Boise, ID (US); Yucheng Wang, Meridian, ID (US); Yiping Wang, Boise, ID (US); John Mark Meldrim, Boise, ID (US)

(21) Appl. No.: 19/224,077

(22) Filed: May 30, 2025

Related U.S. Application Data
(60) Provisional application No. 63/654,683, filed on May 31, 2024.

(51) Int. Cl. G11C 16/04; G11C 5/06; H01L 21/768; H10B 41/10; H10B 41/27; H10B 43/10; H10B 43/27

(52) U.S. Cl. CPC G11C 16/0483; G11C 5/063; H01L 21/76843; H10B 41/10; H10B 41/27; H10B 43/10; H10B 43/27

(57) ABSTRACT

Some embodiments include apparatuses and methods of forming the apparatuses. One of the apparatuses includes a memory device, which includes levels of dielectric materials; levels of conductive materials interleaved with the levels of dielectric materials, the levels of conductive materials including a first conductive level and a second conductive level; a memory cell string including a pillar extending in a direction from the first conductive level to the second conductive level, the second conductive level including a side wall; and a conductive contact extending in the direction from the first conductive level to the second conductive level, the conductive contact including a first portion separated from the first conductive level by a dielectric material, and a second portion adjacent the side wall of the second conductive level.

### PRIORITY APPLICATION

This application claims the benefit of priority to U.S. Provisional Application Ser. No. 63/654,683, filed May 31, 2024, which is incorporated herein by reference in its entirety.

### BACKGROUND

Dimensions of structures of some of the components in a memory device (e.g., a flash memory device) are relatively small (e.g., in nanometer size). At a certain small dimension of a memory device, structural damage (e.g., collapse) in part of the memory device may occur during fabrication. Such collapse can negatively affect yield, cost, performance, and reliability of the memory device.

### BRIEF DESCRIPTION OF THE DRAWINGS

FIG. 1 shows a block diagram of an apparatus in the form of a memory device, according to some embodiments described herein.

FIG. 2 shows a general schematic diagram of a portion of a memory device including a memory array having blocks (blocks of memory cells) and sub-blocks in each of the blocks, according to some embodiments described herein.

FIG. 3 shows a detailed schematic diagram of two blocks of the memory device of FIG. 2, according to some embodiments described herein.

FIG. 4 shows a top view of a structure of a portion of the memory device of FIG. 3 including a region of a memory array, a conductive contact region, and structures between the blocks of the memory device, according to some embodiments described herein.

FIG. 5 shows a side view (e.g., cross-section) of a structure of a portion of the memory device of FIG. 4, including tiers of materials that include respective memory cells and control gates associated with the memory cells, according to some embodiments described herein.

FIG. 6A, FIG. 6B, and FIG. 6C show top views of respective portions of the structure of the memory device of FIG. 4 and FIG. 5, including conductive contacts and dielectric structures (e.g., support structures), according to some embodiments described herein.

FIG. 7 shows a side view (e.g., cross-section) of a portion of the memory device of FIG. 6A and FIG. 6B, including conductive contacts and dielectric structures, according to some embodiments described herein.

FIG. 8A and FIG. 8B show top views (e.g., cross-sections) along lines 8A and 8B in FIG. 7, according to some embodiments described herein.

FIG. 8C shows an enlarged portion of the side view of the memory device of FIG. 7 including a conductive contact and tiers of conductive materials, according to some embodiments described herein.

FIG. 9 shows a memory device that can be a variation of the memory device shown in FIG. 6A, according to some embodiments described herein.

FIG. 10A through FIG. 29B show different views of elements during processes of forming a memory device including forming conductive contacts of the memory device, according to some embodiments described herein.

FIG. 30A through FIG. 32B show different views of elements during processes of forming another memory device including forming conductive contacts of the memory device, according to some embodiments described herein.

FIG. 33A and FIG. 33B show different views of elements of another memory device that can be formed using processes similar the processes of forming the memory device of FIG. 10A through FIG. 29B or FIG. 30A through FIG. 32B, according to some embodiments described herein.

FIG. 34 through FIG. 39 show side views of elements during processes of forming a memory device having multiple decks, according to some embodiments described herein.

### DETAILED DESCRIPTION

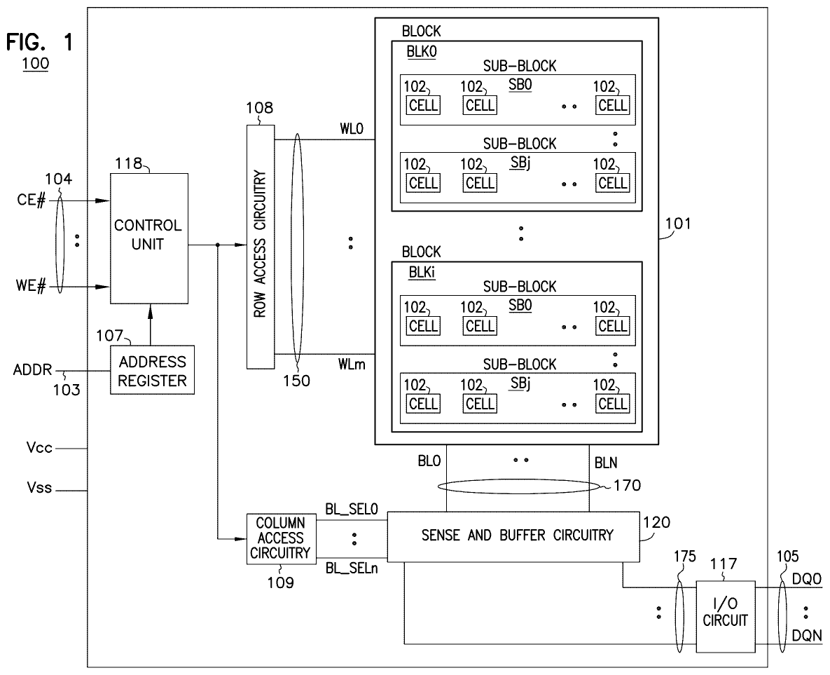

The techniques described herein involve a memory device including memory cells formed in tiers (different physical levels) of the memory device. The tiers include respective levels of conductive materials. The conductive materials form part of control gates (e.g., word lines) associated with the memory cells. The described memory device includes conductive contacts associated with the control gates. The conductive contacts are located over part of the tiers. At least one of the tiers is treated to improve structural support for part of the memory device at the region near the conductive contacts. As described in more detail below, the techniques described herein can improve at least one of yield, cost, performance, and reliability associated with the memory device. Other improvements and benefits of the techniques described herein are further discussed below with reference to FIG. 1 through FIG. 39.

FIG. 1 shows a block diagram of an apparatus in the form of a memory device 100, according to some embodiments described herein. Memory device 100 can include a memory array (or multiple memory arrays) 101 containing memory cells 102 arranged in blocks (blocks of memory cells), such as blocks BLK0 through BLKi. Each of blocks BLK0 through BLKi can include its own sub-blocks, such as sub-blocks SB0 through SBj. A sub-block is a portion of a block. In the physical structure of memory device 100, memory cells 102 can be arranged vertically (e.g., stacked one over another) over a substrate (e.g., a semiconductor substrate) of memory device 100.

As shown in FIG. 1, memory device 100 can include access lines (which can include word lines) 150 and data lines (which can include bit lines) 170. Access lines 150 can carry signals (e.g., word line signals) WL0 through WLm. Data lines 170 can carry signals (e.g., bit line signals) BL0 through BLn. Memory device 100 can use access lines 150 to selectively access memory cells 102 of blocks BLK0 through BLKi and data lines 170 to selectively exchange information (e.g., data) with memory cells 102 of blocks BLK0 through BLKi. Data lines 170 can be shared among blocks BLK0 through BLKi.

Memory device 100 can include an address register 107 to receive address information (e.g., address signals) ADDR on lines (e.g., address lines) 103. Memory device 100 can include row access circuitry 108 and column access circuitry 109 that can decode address information from address register 107. Based on decoded address information, memory device 100 can determine which memory cells 102 of which sub-blocks of blocks BLK0 through BLKi are to be accessed during a memory operation. Memory device 100 can perform a read operation to read (e.g., sense) information (e.g., previously stored information) from memory cells 102 of blocks BLK0 through BLKi, or a write (e.g., programming) operation to store (e.g., program) information in memory cells 102 of blocks BLK0 through BLKi. Memory device 100 can use data lines 170 associated with signals BL0 through BLn to provide information to be stored in memory cells 102 or obtain information read (e.g., sensed) from memory cells 102. Memory device 100 can also perform an erase operation to erase information from some or all of memory cells 102 of blocks BLK0 through BLKi.

Memory device 100 can include a control unit 118 that can be configured to control memory operations of memory device 100 based on control signals on lines 104. Examples of the control signals on lines 104 include one or more clock signals and other signals (e.g., a chip enable signal CE #, a write enable signal WE #) to indicate which operation (e.g., read, write, or erase operation) memory device 100 can perform. Other devices external to memory device 100 (e.g., a memory controller or a processor) may control the values of the control signals on lines 104. Specific values of a combination of the signals on lines 104 may produce a command (e.g., read, write, or erase command) that causes memory device 100 to perform a corresponding memory operation (e.g., read, write, or erase operation).

Memory device 100 can include sense and buffer circuitry 120 that can include components such as sense amplifiers and page buffer circuits (e.g., data latches). Sense and buffer circuitry 120 can respond to signals BL_SEL0 through BL_SELn from column access circuitry 109. Sense and buffer circuitry 120 can be configured to determine (e.g., by sensing) the value of information read from memory cells 102 (e.g., during a read operation) of blocks BLK0 through BLKi and provide the value of the information to lines (e.g., global data lines) 175. Sense and buffer circuitry 120 can also be configured to use signals on lines 175 to determine the value of information to be stored (e.g., programmed) in memory cells 102 of blocks BLK0 through BLKi (e.g., during a write operation) based on the values (e.g., voltage values) of signals on lines 175 (e.g., during a write operation).

Memory device 100 can include input/output (I/O) circuitry 117 to exchange information between memory cells 102 of blocks BLK0 through BLKi and lines (e.g., I/O lines) 105. Signals DQ0 through DQN on lines 105 can represent information read from or stored in memory cells 102 of blocks BLK0 through BLKi. Lines 105 can include nodes within memory device 100 or pins (or solder balls) on a package where memory device 100 can reside. Other devices external to memory device 100 (e.g., a memory controller or a processor) can communicate with memory device 100 through lines 103, 104, and 105.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or alternating current to direct current (AC-DC) converter circuitry.

Each of memory cells 102 can be programmed to store information representing a value of at most one bit (e.g., a single bit), or a value of multiple bits such as two, three, four, or another number of bits. For example, each of memory cells 102 can be programmed to store information representing a binary value “0” or “1” of a single bit. The single bit per cell is sometimes called a single-level cell. In another example, each of memory cells 102 can be programmed to store information representing a value for multiple bits, such as one of four possible values “00”, “01”, “10”, and “11” of two bits, one of eight possible values “000”, “001”, “010”, “011”, “100”, “101”, “110”, and “111” of three bits, or one of other values of another number of multiple bits (e.g., more than three bits in each memory cell). A cell that has the ability to store multiple bits is sometimes called a multi-level cell (or multi-state cell).

Memory device 100 can include a non-volatile memory device, and memory cells 102 can include non-volatile memory cells, such that memory cells 102 can retain information stored thereon when power (e.g., voltage Vcc, Vss, or both) is disconnected from memory device 100. For example, memory device 100 can be a flash memory device, such as a NAND flash (e.g., 3D NAND) or a NOR flash memory device, or another kind of memory device, such as a variable resistance memory device (e.g., a phase change memory device or a resistive Random Access Memory (RAM) device).

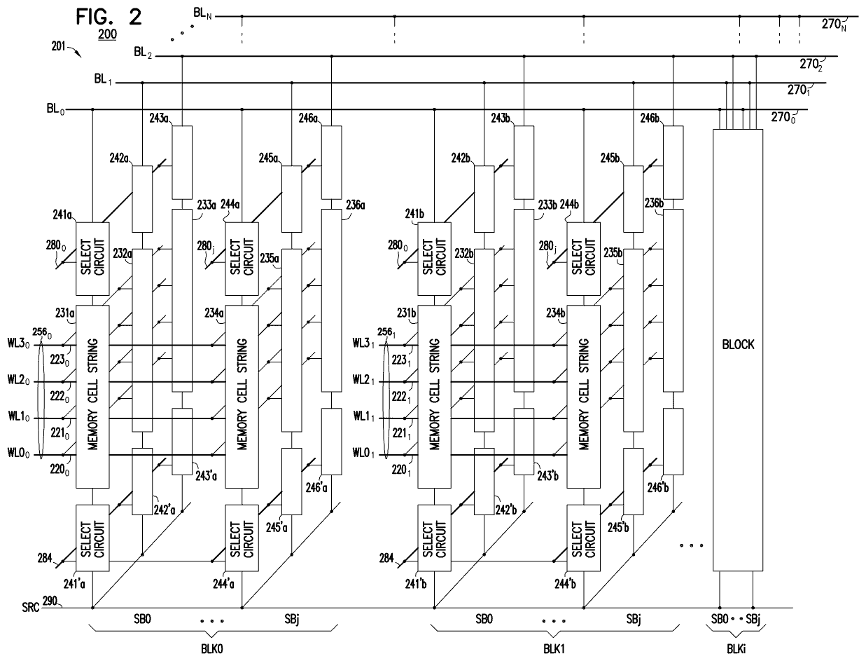

One of ordinary skill in the art may recognize that memory device 100 may include other components, several of which are not shown in FIG. 1 so as not to obscure the example embodiments described herein. At least a portion of memory device 100 can include structures and perform operations similar to or identical to the structures and operations of any of the memory devices described below with reference to FIG. 2 through FIG. 39.

FIG. 2 shows a general schematic diagram of a portion of a memory device 200 including a memory array 201 having blocks (blocks of memory cells) BLK0 through BLKi and sub-blocks SB0 through SBj in each of the blocks, according to some embodiments described herein. Memory device 200 can correspond to memory device 100 of FIG. 1. For example, memory array 201 can form part of memory array 101 of FIG. 1.

As shown in FIG. 2, each sub-block (e.g., SB0 or SBj) has its own memory cell strings that can be associated with (e.g., coupled to) respective select circuits. The sub-blocks of the blocks (e.g., blocks BLK0 through BLKi) of memory device 200 can have the same number of memory cell strings and associated select circuits. For example, sub-block SB0 of block BLK0 has memory cell strings 231a, 232a, and 233a and associated select circuits (e.g., drain select circuits) 241a, 242a, and 243a, respectively, and select circuits (e.g., source select circuits) 241′a, 242′a, and 243′a, respectively. In another example, sub-block SBj of block BLK0 has memory cell strings 234a, 235a, and 236a and associated select circuits (e.g., drain select circuits) 244a, 245a, and 246a, respectively, and select circuits (e.g., source select circuits) 244′a, 245′a, and 246′a, respectively.

Similarly, sub-block SB0 of block BLK1 has memory cell strings 231b, 232b, and 233b, and associated select circuits (e.g., drain select circuits) 241b, 242b, and 243b, respectively, and select circuits (e.g., source select circuits) 241′b, 242′b, and 243′b, respectively. Sub-block SBj of block BLK1 has memory cell strings 234b, 235b, and 236b, and associated select circuits (e.g., drain select circuits) 244b, 245b, and 246b, respectively, and select circuits (e.g., source select circuits) 244′b, 245′b, and 246′b, respectively.

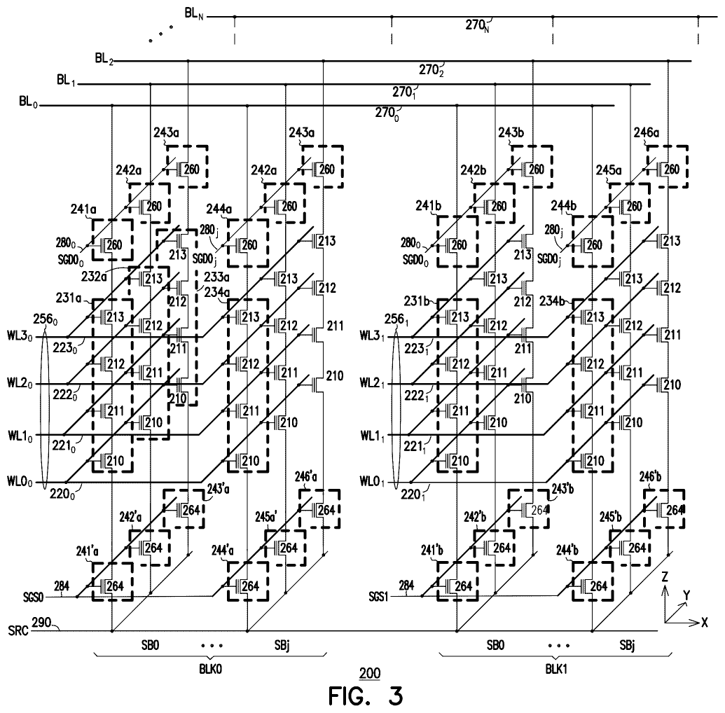

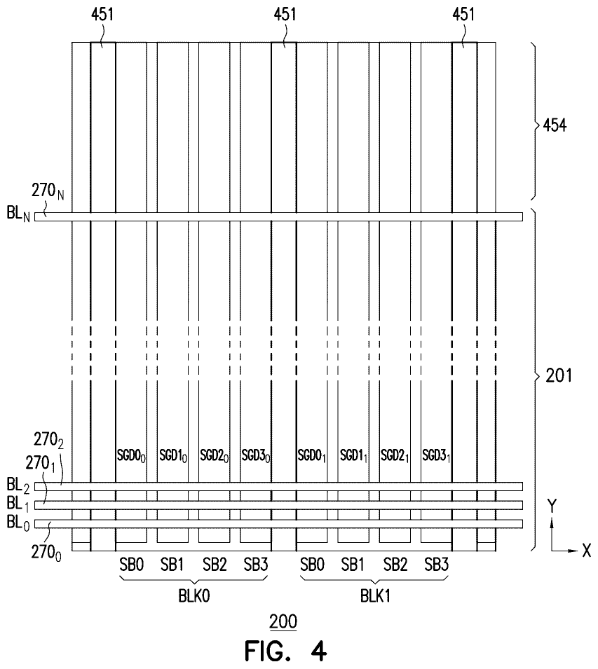

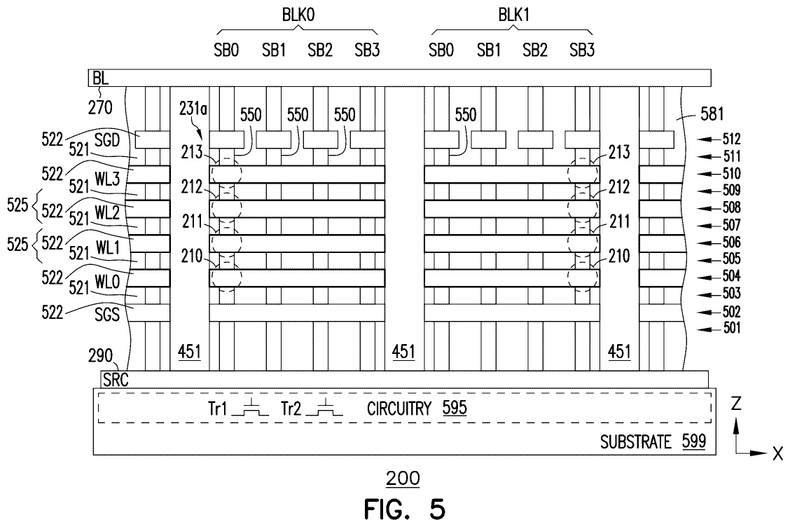

FIG. 2 shows an example of three memory cell strings and their associated circuits in a sub-block (e.g., in sub-block SB0). The number of memory cell strings and their associated select circuits in each sub-block of blocks BLK0 through BLKi can vary. Each of the memory cell strings of memory device 200 can include series-connected memory cells (shown in detail in FIG. 3 and FIG. 4) and a pillar (e.g., pillar 550 in FIG. 5) where the series-connected memory cells can be located (e.g., vertically located) along respective portion of the pillar.

As shown in FIG. 2, memory device 200 can include data lines 270₀ through 270_{N} that carry signals BL₀ through BL_{N}, respectively. Each of data lines 270₀ through 270_{N} can be structured as a conductive line that can include conductive materials (e.g., conductively doped polycrystalline silicon (doped polysilicon), metals, or other conductive materials).

The memory cell strings of blocks BLK0 through BLKi can share data lines 270₀ through 270_{N} to carry information (in the form of signals) read from or to be stored in memory cells of selected memory cells (e.g., selected memory cells in block BLK0 or BLK1) of memory device 200. For example, memory cell strings 231a and 234a (of block BLK0) and 231b and 234b (of block BLK1) can share data line 270₀. Memory cell strings 232a and 235a (of block BLK0) and 232b and 235b (of block BLK1) can share data line 270₁. Memory cell strings 233a and 236a (of block BLK0) and 233b and 236b (of block BLK1) can share data line 270₂.

Memory device 200 can include a source (e.g., a source line, a source plate, or a source region) 290 that can carry a signal (e.g., a source line signal) SRC. Source 290 can be structured as a conductive line or a conductive plate (e.g., conductive region) of memory device 200. Source 290 can be a common source (e.g., common source plate or common source region) of blocks BLK0 through BLKi. Alternatively, each of blocks BLK0 through BLKi can have its own source similar to source 290. Source 290 can be coupled to a ground connection of memory device 200.

Each of the blocks BLK0 through BLKi can have its own group of control gates for controlling access to memory cells of the memory cell strings of the sub-block of a respective block. As shown in FIG. 2, memory device 200 can include control gates (e.g., word lines) 220₀, 221₀, 222₀, and 223₀ in block BLK0 that can be part of conductive paths (e.g., access lines) 256₀ of memory device 200. Memory device 200 can include control gates (e.g., word lines) 220₁, 221₁, 222₁, and 223₁ in block BLK1 that can be part of other conductive paths (e.g., access lines) 256₁ of memory device 200. Conductive paths 256₀ and 256₁ can correspond to part of access lines 150 of memory device 100 of FIG. 1.

As shown in FIG. 2, control gates 220₀, 221₀, 222₀, and 223₀ can be electrically separated from each other. Control gates 220₁, 221₁, 222₁, and 223₁ can be electrically separated from each other. Control gates 220₀, 221₀, 222₀, and 223₀ can be electrically separated from control gates 220₁, 221₁, 222₁, and 223₁. Thus, blocks BLK0 through BLKi can be accessed separately (e.g., accessed one at a time).

FIG. 2 shows memory device 200 including four control gates in each of blocks BLK0 through BLKi as an example. The number of control gates of the blocks (e.g., blocks BLK0 through BLKi) of memory device 200 can be different from four. For example, each of blocks BLK0 through BLKi can include up to hundreds of control gates (or more than hundreds of control gates).

Each of control gates 220₀, 221₀, 222₀, and 223₀ can be part of a structure (e.g., a level) of a conductive material (e.g., a layer of conductive material) located in a level of memory device 200. Control gates 220₀, 221₀, 222₀, and 223₀ can carry corresponding signals (e.g., word line signals) WL0₀, WL1₀, WL2₀, and WL3₀. Memory device 200 can use signals WL0₀, WL1₀, WL2₀, and WL3₀ to selectively control access to memory cells of block BLK0 during an operation (e.g., read, write, or erase operation).

Each of control gates 220₁, 221₁, 222₁, and 223₁ can be part of a structure (e.g., a level) of a conductive material (e.g., a layer of conductive material) located in a level of memory device 200. Control gates 220₁, 221₁, 222₁, and 223₁ can carry corresponding signals (e.g., word line signals) WL0₁, WL1₁, WL2₁, and WL3₁. Memory device 200 can use signals WL0₁, WL1₁, WL2₁, and WL3₁ to selectively control access to memory cells of block BLK1 during an operation (e.g., read, write, or erase operation).

As shown in FIG. 2, in sub-block SB0 of block BLK0, memory device 200 can include a select line (e.g., drain select line) 280₀ that can be shared by select circuits 241a, 242a, and 243a. In sub-block SBj of block BLK0, memory device 200 can include a select line (e.g., drain select line) 280ⱼ that can be shared by select circuits 244a, 245a, and 246a. Block BLK0 can include a select line (e.g., source select line) 284 that can be shared by select circuits 241′a, 242′a, 243′a, 244′a, 245′a, and 246′a.

In sub-block SB0 of block BLK1, memory device 200 can include a select line (e.g., drain select line) 280₀, which is electrically separated from select line 280₀ of block BLK1. Select line 280₀ of block BLK1 can be shared by select circuits 241b, 242b, and 243b. In sub-block SBj of block BLK1, memory device 200 can include a select line (e.g., drain select line) 280ⱼ that can be shared by select circuits 244b, 245b, and 246b. Select lines 280₀ and 280ⱼ of block BLK1 are electrically separated from select lines 280₀ and 280ⱼ of block BLK0. Block BLK1 can include a select line (e.g., source select line) 284 that can be shared by select circuits 241′b, 242′b, 243′b, 244′b, 245′b, and 246′b.

FIG. 2 shows an example where memory device 200 includes one drain select line (e.g., select line 280₀) shared by select circuits (e.g., select circuits 241a, 242a, or 243a) in a sub-block (e.g., sub-block SB0 of block BLK0). However, memory device 200 can include multiple drain select lines shared by select circuits in a sub-block. FIG. 2 shows an example where memory device 200 includes one source select line (e.g., select line 284) shared by source select circuits (e.g., select circuits 241′a, 242′a, or 243′a) in a sub-block (e.g., sub-block SB0 of block BLK0). However, memory device 200 can include multiple source select lines shared by source select circuits in a sub-block.

In FIG. 2, each of the drain select circuits of memory device 200 can include a drain select gate (e.g., a transistor, shown in FIG. 3) between a respective data line and a respective memory cell string. The drain select gate (e.g., transistor) can be controlled (e.g., turned on or turned off) by a signal on the respective drain select line based on voltages provided to the signal.

In FIG. 2, each of the source select circuits of memory device 200 can include a source select gate (e.g., a transistor, shown in FIG. 3) coupled between source 290 and a respective memory cell string. The source select gate (e.g., transistor) can be controlled (e.g., turned on or turned off) by a signal on a respective source select line based on a voltage provided to the signal.

FIG. 3 shows a detailed schematic diagram including blocks of the blocks BLK0 and BLK1 of memory device 200 of FIG. 2, according to some embodiments described herein. In FIG. 3, directions X, Y, and Z can be relative to the physical directions (e.g., three dimensions (3D)) of the structure of memory device 200. For example, the Z-direction can be a direction perpendicular to (e.g., vertical direction with respect to) a substrate of memory device 200 (e.g., a substrate 599 shown in FIG. 5). The Z-direction is perpendicular to the X-direction and Y-direction (e.g., the Z-direction is perpendicular to an X-Y plane of memory device 200).

For simplicity, only some of the memory cell strings and some of the select circuits of memory device 200 of FIG. 2 are labeled in FIG. 3. As shown in FIG. 3, each select line can carry an associated separate select signal. For example, in sub-block SB0 of block BLK0, select line (e.g., drain select line) 280₀ can carry signal (e.g., drain select-gate signal) SGD0₀. In sub-block SBj of block BLK0, select line (e.g., drain select line) 280ⱼ can carry signal (e.g., drain select-gate signal) SGD0ⱼ. Sub-blocks SB0 and SBj of block BLK0 can share select line 284 that can carry signal (e.g., source select-gate signal) SGS0.

In sub-block SB0 of block BLK1, select line (e.g., drain select line) 280₀ can carry signal (e.g., drain select-gate signal) SGD0₀. In sub-block SBj of block BLK1, select line (e.g., drain select line) 280ⱼ can carry signal (e.g., drain select-gate signal) SGD0ⱼ. Sub-blocks SB0 and SBj of block BLK1 can share select line 284 that can carry signal (e.g., source select-gate signal) SGS1.

For simplicity, similar or the same elements in the memory devices (e.g., memory device 200) described herein are given the same label. For example, as shown in FIG. 3, similar drain select lines (and their associated signals) are given the same labels for simplicity. However, as shown in FIG. 3, the drain select lines (from the same block or from different blocks) of memory device 200 are electrically separated from each other and carry different signals (although the signals are given the same labels).

As shown in FIG. 3, memory device 200 can include memory cells 210, 211, 212, and 213; select gates (e.g., drain select gates or transistors) 260; and select gates (e.g., source select gates) 264 that can be physically arranged in three dimensions (3D), such as X, Y, and Z directions (e.g., dimensions), with respect to the structure (shown in FIG. 4) of memory device 200.

In FIG. 3, each of the memory cell strings (e.g., memory cell string 231a) of memory device 200 can include series-connected memory cells that include one of memory cells 210, one of memory cells 211, one of memory cells 212, and one of memory cells 213. FIG. 3 shows an example of four memory cells 210, 211, 212, and 213 in each memory cell string. The number of memory cells in each memory cell string can vary. For example, each memory string can include up to hundreds (or more) of memory cells.

As shown in FIG. 3, each drain select circuit (e.g., select circuit 241a) can include one of select gates 260. Each source select circuit (e.g., select circuit 241′a) can include one of select gates 264.

Each of select gates 260 in FIG. 3 can operate like a transistor. For example, select gate 260 of select circuit 241a can operate like a field effect transistor (FET), such as a metal-oxide semiconductor FET (MOSFET). An example of such a MOSFET includes an n-channel MOS (NMOS) transistor.

A select line (e.g., select line 280₀ of sub-block SB0 of block BLK0) can carry a signal (e.g., signal SGD0₀) but it does not operate like a switch (e.g., a transistor). A select gate (e.g., select gate 260 of select circuit 241a) can receive a signal (e.g., signal SGD0₀) from a respective select line (e.g., select line 280₀ of sub-block SB0 of block BLK0) and can operate like a switch (e.g., a transistor).

In the physical structure of memory device 200, a select line (e.g., select line 280₀ of sub-block SB0 of block BLK0) can be a structure (e.g., a level) of a conductive material (e.g., a layer (e.g., a piece) or a region of conductive material) located in a single level of memory device 200. The conductive material can include metal, doped polysilicon, or other conductive materials.

In the physical structure of memory device 200, a select gate (e.g., select gate 260 of select circuit 241a of sub-block SB0 of block BLK0) can include (can be formed from) a portion of the conductive material of a respective select line (e.g., select line 280₀ of sub-block SB0 of block BLK0), a portion of a channel material (e.g., polysilicon channel), and a portion of a dielectric material (e.g., similar to a gate oxide of a transistor (e.g., FET) between the portion of the conductive material and the portion of the channel material.

FIG. 3 shows an example where memory device 200 includes one drain select gate (e.g., select gate 260) in each drain select circuit, and one source select gate (e.g., select gate 264) in each source select circuit coupled to a memory cell string. However, memory device 200 can include multiple drain select gates (e.g., multiple select gates 260 connected in series) in each drain select circuit, multiple source select gates (e.g., multiple select gates 264 connected in series) in each source select circuit, or both multiple drain select gates and multiple source select gates coupled to a memory cell string.

FIG. 4 shows a top view of a structure of a portion of memory device 200 of FIG. 2 and FIG. 3 including a region of memory array 201 including blocks BLK0 and BLK1, a region 454, and structures 451 between blocks, according to some embodiments described herein. For simplicity, some elements of memory device 200 (and other memory devices described herein) may be omitted from a particular figure of the drawings so as not to obscure the view or the description of the element (or elements) being described in that particular figure. Also, for simplicity, cross-sectional lines (e.g., hatch lines) are omitted from some or all the elements shown in the drawings described herein. Some elements of memory device 200 may be omitted from a particular figure of the drawings so as not to obscure the view or the description of the element (or elements) being described in that particular figure. Further, the dimensions (e.g., physical structures) of the elements of memory device 200 (and other memory devices) in the drawings described herein are not scaled. Moreover, the description of the same elements of memory device 200 described above with reference to FIG. 2 and FIG. 3 are not repeated.

In FIG. 4, structures 451 can be formed to separate (physically separate) one block and another block of memory device 200. Two adjacent blocks (e.g., blocks BLK0 and BLK1) can be separated from each other by one of structures 451. Each structure 451 can have a length in the Y-direction. Each structure 451 can include a dielectric material (e.g., silicon dioxide) or a combination of a dielectric material and additional material (e.g., a non-conductive material). Each structure 451 can include a slit (not labeled) and materials (not labeled) formed in (e.g., filled in) the slit. The slit can include (or can be part of) a trench between adjacent blocks (e.g., blocks BLK0 and BLK1). Structures 451 can be called a dielectric structure or a slit structure. The regions of memory device 200 at which structures 451 are located can be called slit regions.

As shown in FIG. 4, block BLK0 can include sub-blocks (e.g., four sub-blocks) SB0, SB1, SB2, and SB3 and select lines (e.g., four drain select lines) associated with signals SGD0₀, SGD1₀, SGD2₀, and SGD3₀, respectively. The select lines can include respective conductive regions (e.g., conductive materials) that are electrically separated from each other (in the X-direction) and can be located on the same level (with respect to the Z-direction). The select lines associated with signals SGD0₀, SGD1₀, SGD2₀, and SGD3₀ can be located over (with respect to the Z-direction) the control gates (under the select lines) of block BLK0. As shown in FIG. 4, each of the select lines (associated with signals SGD0₀, SGD1₀, SGD2₀, and SGD3₀) can have length in the Y-direction from memory array 201 to region 454. FIG. 4 shows an example where each block of memory device 200 can have four sub-blocks SB0, SB1, SB2, and SB3. However, the number of sub-blocks can be different from four.

Block BLK1 can have a structure like block BLK0. As shown in FIG. 4, block BLK1 can include sub-blocks SB0, SB1, SB2, and SB3, select lines (e.g., drain select lines) SGD0₁, SGD1₁, SGD2₁, and SGD3₁.

FIG. 5 shows a side view (e.g., cross-section) of a structure of a portion of memory device 200 of FIG. 4 including tiers (tiers of materials) 525 that include respective memory cells and control gates associated with (e.g., to control) the memory cells, according to some embodiments described herein. FIG. 5 also partially shows other blocks (on the left and right sides of blocks BLK0 and BLK1) of memory device 200.

As shown in FIG. 5, memory device 200 can include a substrate 599, source 290 formed over substrate 599, and different levels 501 through 512 over substrate 599 in the Z-direction. Levels 501 through 512 are physical device levels of memory device 200 over substrate 599. Memory device 200 can include a dielectric material 581 formed over at least a portion of memory device 200. Memory cells 210, 211, 212, and 213 of the memory cell strings (e.g., memory cell string 231a in FIG. 3) of respective sub-blocks SB0, SB1, SB3, and SB3 of each of blocks BLK0 and BLK1 can be formed over substrate 599 and source 290 (e.g., formed vertically in the Z-direction in respective levels among levels 501 through 512).

In FIG. 5, a data line 270 can be one of data lines 270₀ through 270_{N} in FIG. 4. Signal BL can be one of signals BL₀ through BL_{N} in FIG. 4.

In FIG. 5, the select lines (e.g., four drain select lines in the X-direction) indicated by signal SGD can correspond to respective select lines (e.g., drain select lines) of a respective block of blocks BLK0 and BLK1. For example, in sub-blocks SB0, SB1, SB2, and SB3 of block BLK0, the select lines (e.g., four drain select lines) indicated by signal SGD can correspond to respective select lines associated with signals SGD0₀, SGD1₀, SGD2₀, and SGD3₀ of block BLK0 shown in FIG. 4. In another example, in sub-blocks SB0, SB1, SB2, and SB3 of block BLK1, the select lines (e.g., four drain select lines in the X-direction) indicated by signal SGD can correspond to respective select lines associated with signals SGD0₁, SGD1₁, SGD2₁, and SGD3₁ of block BLK1 shown in FIG. 4.

As shown in FIG. 5, the select lines (e.g., four drain select lines) in the same block (e.g., block BLK0) can include respective conductive regions (e.g., four conductive regions) that are electrically separated from each other and can be located on the same level (e.g., level 512) in the Z-direction of memory device 200 and located over the control gates (in the Z-direction) of the respective block.

The select lines (e.g., source select lines) indicated by signal SGS (on level 501) can correspond to respective select lines of blocks BLK0 and BLK1. For example, in block BLK0, the select line indicated by signal SGS can correspond to the select line (e.g., source select line) associated with signals SGS0 of block BLK0 shown in FIG. 3. In another example, in block BLK1, the select line indicated by signal SGS can correspond to the select line (e.g., source select line) associated with signals SGS1 of block BLK1 shown in FIG. 3.

In FIG. 5, for simplicity, control gates (e.g., four control gates) of blocks BLK0 and BLK1 are indicated by the same signals WL0, WL1, WL2, and WL3. For example, in block BLK0, the control gates indicated by signals WL0, WL1, WL2, and WL3 can correspond to respective control gates associated with signals WL0₀, WL1₀, WL2₀, and WL3₀, respectively, of block BLK0 shown in FIG. 3. In another example, in block BLK1 in FIG. 5, the control gates indicated by signals WL0, WL1, WL2, and WL3 can correspond to respective control gates associated with signals WL0₁, WL1₁, WL2₁, and WL3₁, respectively, of block BLK1 shown in FIG. 3.

As shown in FIG. 5, memory device 200 can include dielectric materials (e.g., silicon dioxide) 521 located on levels 503, 505, 507, 509, and 511. Dielectric materials 521 in a respective block are interleaved with conductive materials 522. Conductive materials 522 can form respective control gates (associated with signals WL0, WL1, WL2, and WL3) in the respective block. As shown in FIG. 5, dielectric materials 521 can be located on respective levels among levels 501 through 512. Conductive materials 522 can be located on respective levels (e.g., levels 502, 504, 506, 508, 510, and 512) among levels 501 through 512 that are interleaved with the levels of dielectric materials 521. Examples of conductive materials 522 (which form the control gates) include a single conductive material (e.g., a single metal, e.g., tungsten) or a combination of different layers of conductive materials. For example, each of the control gates of blocks BLK0 and BLK1 can include (e.g., can have multi-layers of) aluminum oxide, titanium nitride, tungsten.

The levels of dielectric material 521 and the levels of conductive materials 522 can form tiers 525 of memory device 200. Each tier 525 can include a level of dielectric material 521 and a level of conductive material 522. For simplicity, only some of tiers 525 are labeled in FIG. 5. As shown in FIG. 5, tiers 525 can be located one over another and can include respective levels of memory cells 210, 211, 212, and 213, and control gates associated with the memory cells. FIG. 5 shows a few tiers (e.g., only two tiers 525 are labeled) of memory device 200 as an example. However, memory device 200 can include up to hundreds of tiers (or more than hundreds of tiers).

As shown in FIG. 5, memory device 200 can include pillars (memory cell pillars) 550 in blocks BL0 and BLK1. Each of pillars 550 can be part of a respective memory cell string (e.g., memory cell string 231a). Each of pillars 550 can have length extending outwardly (e.g., extending vertically in the direction of the Z-direction) from substrate 599 between substrate 599 and data line 270. As shown in FIG. 5, the Z-direction is also a direction at which the length of pillar 550 extends from one tier to another tier, which is also a direction from levels of dielectric materials 521 to levels of conductive materials 522.

As shown in FIG. 5, memory cells 210, 211, 212, and 213 of respective memory cell strings (e.g., memory cell string 231a) can be located in different levels (e.g., levels 504, 506, 508, and 510) in the Z-direction of memory device 200. The control gates (associated with signals WL0, WL1, WL2, and WL3) of each of blocks BLK0 and BLK1 can be located on the same levels (e.g., levels 504, 506, 508, and 510) at which memory cells 210, 211, 212, and 213 are located. Thus, memory cells 210, 211, 212, and 213 and the control gates of blocks BLK0 and BLK1 can be located (e.g., vertically located) along respective portions (e.g., portions on levels 504, 506, 508, and 510) of pillars 550 in the Z-direction.

Substrate 599 of memory device 200 can include monocrystalline (also referred to as single-crystal) semiconductor material. For example, substrate 599 can include monocrystalline silicon (also referred to as single-crystal silicon). The monocrystalline semiconductor material of substrate 599 can include impurities, such that substrate 599 can have a specific conductivity type (e.g., n-type or p-type).

As shown in FIG. 5, memory device 200 can include circuitry 595 located in (e.g., formed in) substrate 599. At least a portion of the circuitry can be located in a portion of substrate 599 that is under (e.g., directly under) memory cell strings of blocks BLK0 and BLK1. Circuitry 595 can include transistors (e.g., Tr1 and Tr2) that can be part of decoder circuits, driver circuits (e.g., word line drivers), buffers, sense amplifiers, charge pumps, and other circuitry of memory device 200.

In FIG. 5, source 290 can include a conductive material (or materials, e.g., different levels of different materials) and can have a length extending in the X-direction. FIG. 5 shows an example where source 290 can be formed over a portion of substrate 599 (e.g., by depositing a conductive material over substrate 599). Alternatively, source 290 can be formed in or formed on a portion of substrate 599 (e.g., by doping a portion of substrate 599).

The select lines (associated with signals SGS and SGD) of blocks BLK0 and BLK1 can have the same material (or materials) as the control gates (associated with signals WL0, WL1, WL2, and WL3) of blocks BLK0 and BLK1. Alternatively, the select gates associated with signal SGS, SGD, or both have material (or materials) different from the material of the control gates.

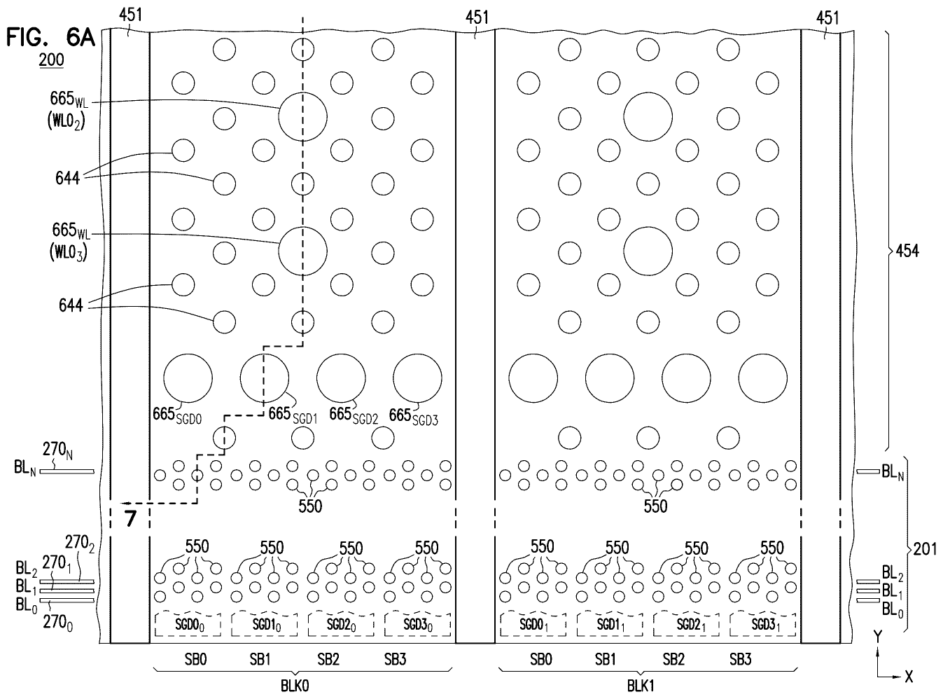

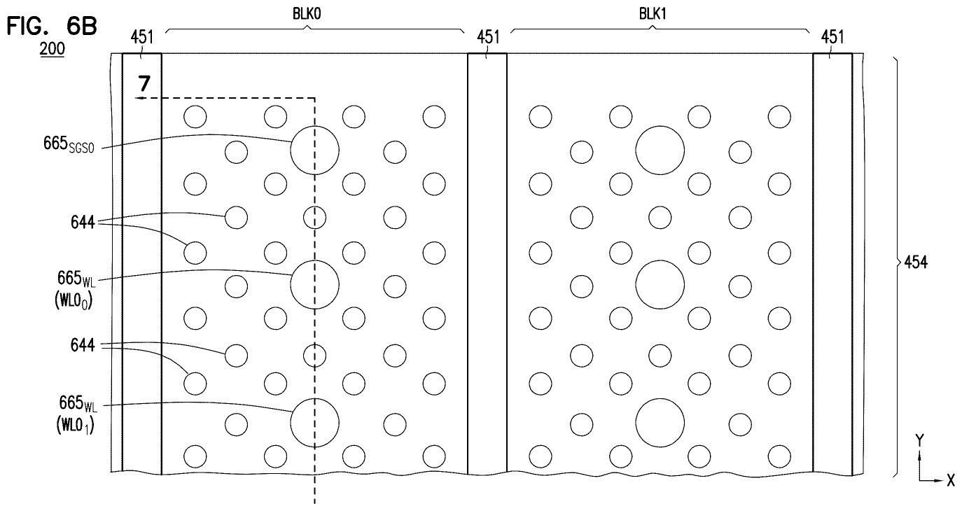

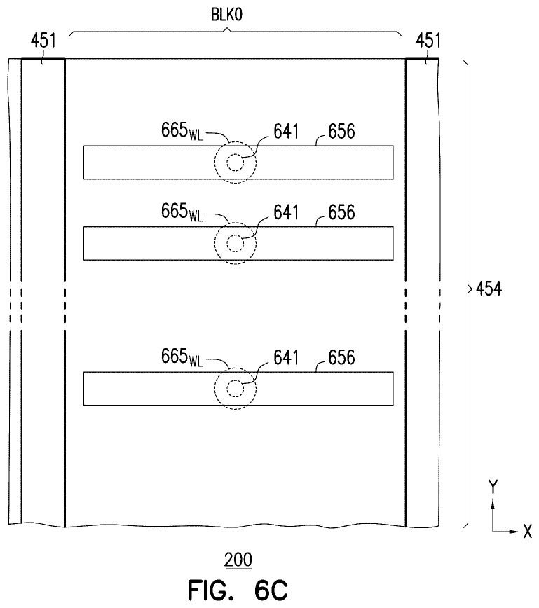

FIG. 6A and FIG. 6B show top views of a structure of memory device 200 of FIG. 4, according to some embodiments described herein. FIG. 6C shows a top view of additional elements of memory device 200 of FIG. 4, according to some embodiments described herein. FIG. 6A shows top views of pillars 550 located in the region included in memory array 201, which is adjacent region 454. As shown in FIG. 6A and FIG. 6B, in region 454, memory device 200 can include conductive contacts (e.g., word line contacts) 665_{WL}, conductive contacts (e.g., drain select line contacts) 665_{SGDO}, 665_{SGD1}, 665_{SGD2}, and 665_{SGD3}), and conductive (e.g., source select line contact) 665_{SGS0} (FIG. 6B) in region 454. Conductive contacts 665_{WL} can include metal (e.g., tungsten or other conductive materials). Although not shown in FIG. 6A and FIG. 6B for simplicity, memory device can include conductive lines 656 (as shown in FIG. 6C) and conductive portions 641 coupled to respective conductive contacts (e.g., conductive contacts 665_{WL}, as shown in FIG. 6C) of memory device 200.

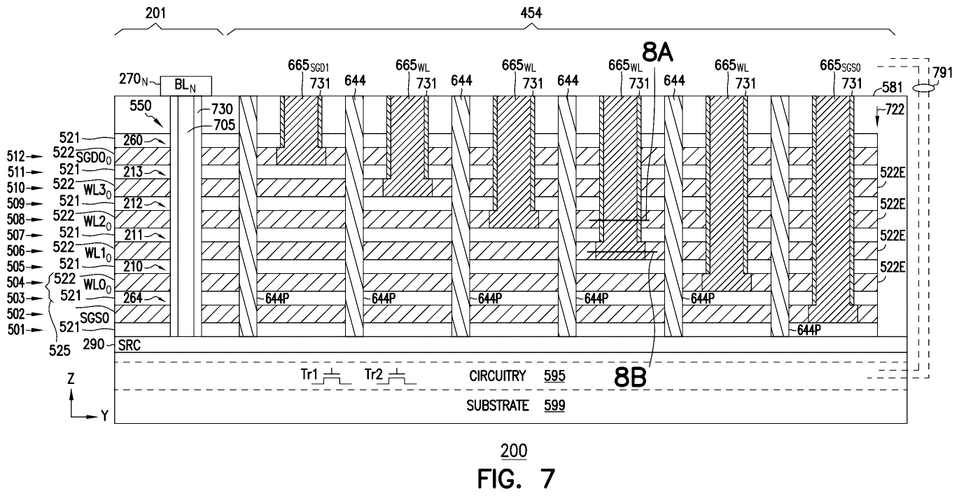

Conductive contacts 665_{WL} can contact (form electrical connection with) respective control gates (located under conductive contacts 665_{WL}, hidden from the top view of FIG. 6A and FIG. 6B). Conductive contacts 665_{WL} can be part of respective access lines (e.g., word lines) of memory device 200. Conductive contacts 665_{WL} allow signals (e.g., signals WL0₀, WL1₀, WL2₀, and WL3₀ in block BLK0 in FIG. 3) to be provided to respective control gates of block BLK0 through conductive contacts 665_{WL} in FIG. 6A and FIG. 6B. FIG. 7 (described in more detail below) shows side views (e.g., cross-sections) of conductive contacts 665.

Similarly, for block BLK1 in FIG. 6A and FIG. 6B, conductive contacts (e.g., not labeled) can be formed at region 454 to allow signals (e.g., signals WL0₁, WL1₁, WL2₁, and WL3₁ in block BLK1 shown in FIG. 3) to be provided to respective control gates of block BLK1 through the conductive contacts at region 454. Region 454 can be called conductive contact region (e.g., word line conductive contact region) of memory device 200.

FIG. 6A and FIG. 6B also show top views of dielectric structures 644. Each of dielectric structures 644 can include a pillar (e.g., dielectric pillar 644P, shown in FIG. 7) having a length extending the Z-direction. Dielectric structures 644 can include a dielectric material (e.g., silicon dioxide).

Dielectric structures 644 can be formed to provide structural support for a portion (e.g., region 454) of memory device 200 (e.g., during part of the processes of forming memory device 200). Dielectric structures 644 can be called support structures at region 454 of memory device 200.

As shown from the top view (e.g., cross-section parallel to the X-Y plan) in FIG. 6A and FIG. 6B, conductive contacts 665_{WL}, 665_{SGDO}, 665_{SGD1}, 665_{SGD2}, and 665_{SGD3}, and 665_{SGS0} can be located side-by-side with respective portions of dielectric structures 644.

In FIG. 6A, select lines associated with signals SGD0₀, SGD1₀, SGD2₀, and SGD3₀ in block BLK0 and signals SGD0₁, SGD1₁, SGD2₁, and SGD3₁ in block BLK1 are partially shown as dotted lines. Each of sub-blocks SB0, SB1, SB2, and SB3 can include multiple rows of pillars 550 associated with a respective select line (one of the select lines associated with signals SGD0₀, SGD1₀, SGD2₀, and SGD3₀). As shown in FIG. 6A, the multiple rows of pillars 550 can be located one after another in the X-direction (having lengths parallel to the Y-direction). FIG. 6A shows an example where each sub-block includes four rows of pillars 550. However, the number of rows in the sub-blocks can be less than four or greater than four.

In FIG. 6A, data lines 270₀ through 270_{N} are partially shown for simplicity. Data lines 270₀ through 270_{N} can extend across (in the X-direction) the blocks (e.g., blocks BL0 and BL1) and can be located over and in electrical contact with pillars 550. Connections (e.g., vertical connections in the Z-direction) between pillars 550 and data lines 270₀ through 270_{N} are not shown in FIG. 6A through FIG. 6C. However, each pillar 550 in the same sub-block of a block can be coupled to a separate (e.g., unique) data line among data lines 270₀ through 270_{N}.

FIG. 6C shows a top view of a portion of memory device 200 including conductive lines 656 associated with block BLK0. For simplicity, only some of conductive lines 656 of memory device 200 are shown in FIG. 6C. Conductive lines 656 can be part of conductive paths (e.g., conductive paths 791 in FIG. 7) coupled to components (e.g., word line drivers) of circuitry 595 (FIG. 7) of memory device 200. As shown in FIG. 6C, memory device 200 can include conductive portions 641 that are located under and coupled to respective conductive contacts 665_{WL}. Conductive lines 656 of a block (e.g., BLK0) can be formed (e.g., patterned) such that they can be electrically separated from other conductive lines 656 (not shown) of another block (e.g., block BLK1).

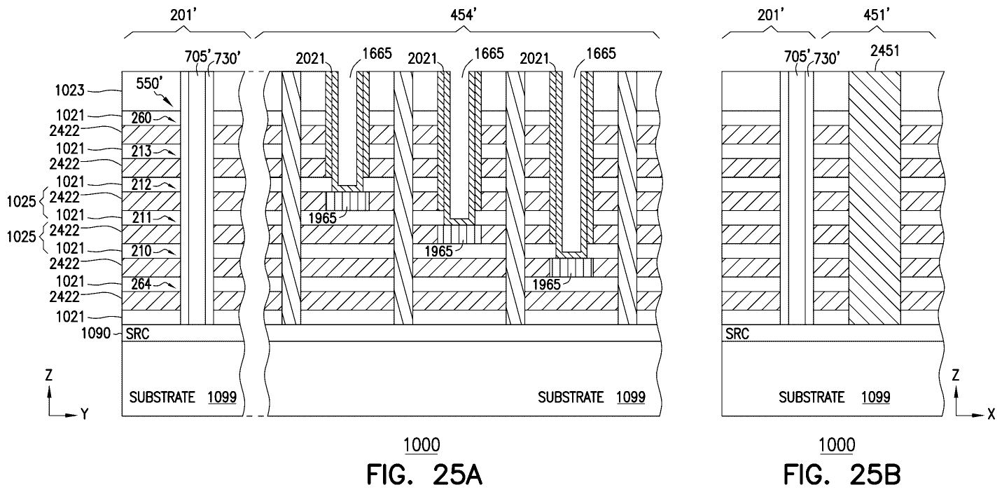

Conductive portions 641 can be similar to (or the same as) conductive portions 2541 (FIG. 25A). In FIG. 6C, a conduct portion 641 and a corresponding conductive contact 665 (that are coupled to the same conductive line 656) can be called a conductive contact structure (e.g., a word line contact structure) associated with a respective conductive line 656.

A side view (e.g., cross-section) along line 7-7 in FIG. 6A and FIG. 6B of block BLK0 is shown in FIG. 7.

FIG. 7 shows a side view of a portion of memory device 200 including conductive contacts 665_{WL}, 665_{SGD1}, and 665_{SGS0} in region 454, and pillar 550 in memory array 201, according to some embodiments described herein. Levels 501 through 512 and tiers 525 of memory device 200 in FIG. 7 are the same as those shown in FIG. 5. As shown in FIG. 7, pillar 550 can be located in the portion of memory device 200 that includes memory array 201, which is also shown in top view in FIG. 4 and FIG. 6A and FIG. 6B. Pillar 550 can extend through conductive materials 522 (which form the control gates and the select lines) and dielectric materials 521 in the portions that include memory array 201.

As shown in FIG. 7, memory device 200 can include a structure 730 and a dielectric material 705 that can be part of pillar 550. Structure 730 and a dielectric material 705 can extend continuously (in the Z-direction) along the length of the respective pillar 550. Dielectric material 705 can include silicon dioxide. Structure 730 can be electrically coupled to source 290 and a respective data line (e.g., one of data line 270₀ through 270_{N} in FIG. 3 and FIG. 6). Structure 730 of a respective pillar 550 in a block is adjacent portions of respective control gates of that block. For example, structure 730 of pillar 550 in block BLK0 is adjacent the control gates associated with signals WL0₀, WL1₀, WL2₀, and WL3₀, respectively.

Structure 730 can include a conductive structure that can be part of a conductive path (e.g., pillar channel structure) to conduct current between a respective data line (e.g., one of data line 270₀ through 270_{N} in FIG. 3 and FIG. 6A) coupled to structure 730 and source 290. Structure 730 can also include a material (or materials) that can form a charge storage element (e.g., a memory element) of a respective memory cell (among memory cells 210, 211, 212, and 213) located along a portion of pillar 550. As an example, structure 730 can be part of an ONOS (SiO₂, Si₃N₄, SiO₂, Si) where Si₃N₄ material can form a charge storage element of a respective memory cell, and Si material can be part of the pillar channel structure of pillar 550. In another example, structure 730 include can be part of a SONOS (Si, SiO₂, Si₃N₄, SiO₂, Si) structure, a TANOS (TaN, Al₂O₃, Si₃N₄, SiO₂, Si) structure, a MANOS (metal, Al₂O₃, Si₃N₄, SiO₂, Si) structure, or other structures. Alternatively, structure 730 can include a floating gate structure (e.g., polysilicon structure) where the floating gate structure can form a charge storage element of a respective memory (among memory cells 210, 211, 212, and 213) located along a portion of pillar 550.

As shown in FIG. 7, the control gates associated with signals WL0₀, WL1₀, WL2₀, and WL3₀, and the select lines associated with signals (e.g., drain select signal and source select signal) SGD0₀ and SGS0 can be structured (e.g., patterned), such that they may have the same length in the Y-direction. For example, the control gates (formed from respective materials 522) associated with signals WL0₀, WL1₀, WL2₀, and WL3₀ can have the same length (in the Y-direction) measuring between pillar 550 and edges 522E of respective the control gates. Edges 522E are part of respective conductive materials 522. As shown in FIG. 7, the control gates associated with signals WL0₀, WL1₀, WL2₀, and WL3₀ can have the same length, such that edges 522E can be aligned (e.g., vertically aligned) with each other at a reference location (e.g., reference point) 722 in the X-direction.

As shown in FIG. 7, dielectric structures 644 can include respective pillars (dielectric pillars) 644P that can include respective lengths extending in the Z-direction. Pillars (dielectric pillars) 644P can be called support pillars in region 454 of memory device 200.

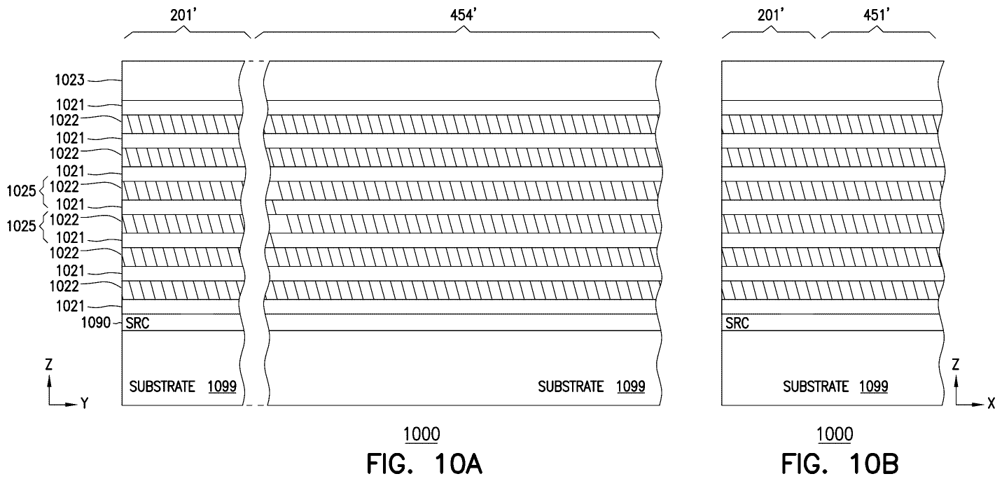

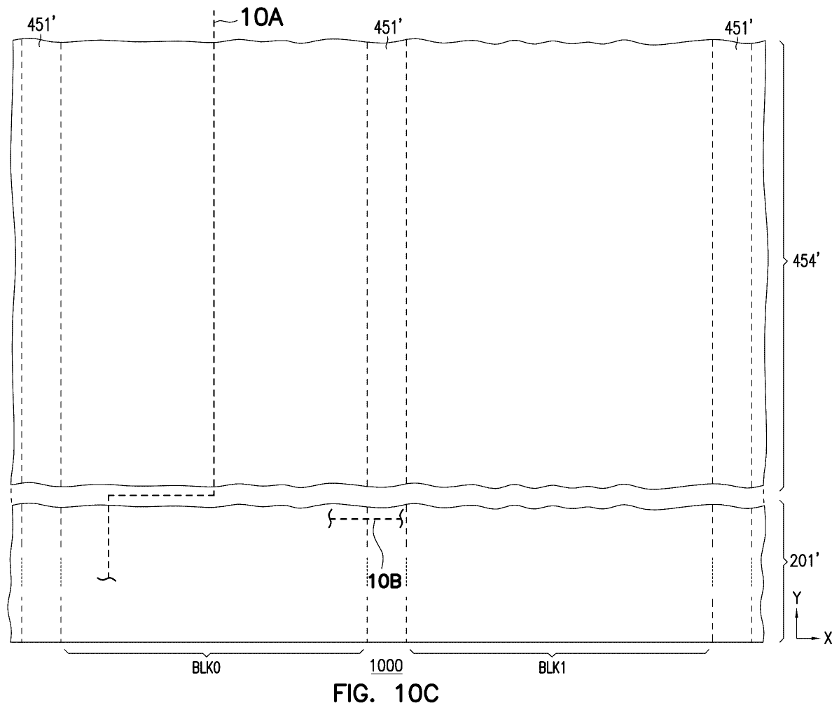

During the processes of forming memory device 200 that can be similar to the processes of forming memory device 1000 of FIG. 10A through FIG. 29A, collapse (e.g., in the Z-direction) of some structures (e.g., collapse in part of the levels of conductive materials 522 in region 454) of memory device 200 may occur. Dielectric structure 644 can be formed in memory device 200 to prevent such collapse.

As shown in FIG. 7, dielectric structures 644 can extend through (e.g., go through) and contact respective portion of dielectric materials 521 and conductive materials 522. Dielectric structures 644 can contact (e.g., land on) source 290. Dielectric structures 644 are electrically separated from conductive materials 522. Each of dielectric structures 644 can contact dielectric materials 521 and conductive materials 522. Dielectric structures 644 are electrically separated from conductive materials 522. As shown in FIG. 7, dielectric structure 644 can be between (in the Y-direction in FIG. 7) pillar (memory cell pillar) 550 and edges 522E of respective levels of conductive materials 522.

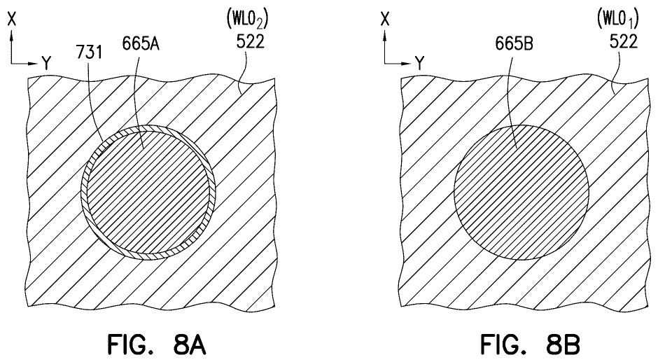

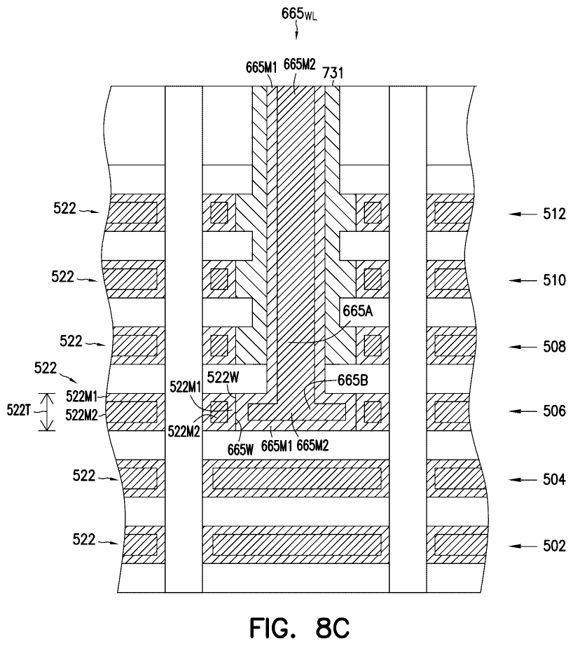

As shown in FIG. 7, memory device 200 can include conductive paths (e.g., conductive routings) 791 to form circuit paths between circuitry 595 and other elements of memory device 200. For example, conductive lines 656 (FIG. 6C) associated with the control gates (e.g., control gates associated with signals WL0₀, WL1₀, WL2₀, and WL3₀ in FIG. 7) of memory device 200 can be part of (or can be coupled to) conductive paths 791. This allows the control gates to couple to circuitry 595 through conductive lines conductive lines 656 (FIG. 6C) and conductive paths 791 (FIG. 7). Different views (e.g., cross-sections) along lines 8A and 8B in FIG. 7 are shown in FIG. 8A and FIG. 8B, respectively.

FIG. 8A and FIG. 8B show top views (e.g., cross-sections) along lines 8A and 8B, respectively, of FIG. 7, according to some embodiments described herein. FIG. 8C shows an enlarged portion of memory device 200 of FIG. 7.

As shown in FIG. 8A and FIG. 8C, portion 665A can be surrounded by liner 731, which is surrounded by the conductive material 522 that forms the control gate associated with signal WL2₀. As shown in FIG. 8B and FIG. 8C, portion 665B is adjacent the conductive material 522 that forms the control gate associated with signal WL0₁.

FIG. 8C shows levels of conducive materials 522 that have similar or the same structure and features. For simplicity, detail of the structure and materials of only one level of conductive materials 522 is described here.

As described above, each of levels of conducive materials 522 can form part of a control gate (e.g., one of the control gates associated with memory cells 210, 211, 212, and 213 in FIG. 7). As shown in FIG. 8C, each level of conductive materials (each conducive level) can include a thickness 522T (in the Z-direction) and a side wall 522W. The height of side wall 522W and thickness 522T can have the same dimension (e.g., measured in meter unit). Conductive contact 665_{WL} can include a side wall 665W. As shown in FIG. 8C, side wall 522W and 665W are adjacent (e.g., contacting) each other.

As shown in FIG. 8C, portion 665A of conductive contact 665_{WL} is separated from the level of conductive materials 522 located on level 508 by liner 731. Portion 665B of conductive contact 665_{WL} is adjacent (e.g., contacting) side wall 552W of level of conductive materials 522 on level 506.

Each level of conductive materials 522 can include a conductive material 522M1 and a conductive material 522M2 adjacent (e.g., contacting) conductive material 522M1. Material 522M1 can be different from material 522M2.

Conductive contact 665_{WL} can include a conductive material 665M1 and a conductive material 665M2 adjacent (e.g., contacting) conductive material 665m1. Material 665M1 can be different from material 665M2.

Conductive materials 522M1, 522M2, 665M1, and 665M2 can include different combinations of conductive materials. For example, conductive materials 522M1, 522M2, 665M1, and 665M2 can be different from each other. In another example, conductive materials 522M1 and 665M1 can be the same material (e.g., titanium nitride) and conductive materials 522M2 and 665M2 can be the same material (e.g., tungsten).

FIG. 8C shows an example where each level of conductive materials 522 includes two materials 522M1 and 522M2. However, the number of materials of each level of conductive materials 522 can be different from two. For example, each level of conductive materials 522 can include one conductive material such that either material 522M1 and or material 522M2 can be omitted (not included). In another example, each level of conductive materials 522 can include more than two conductive materials.

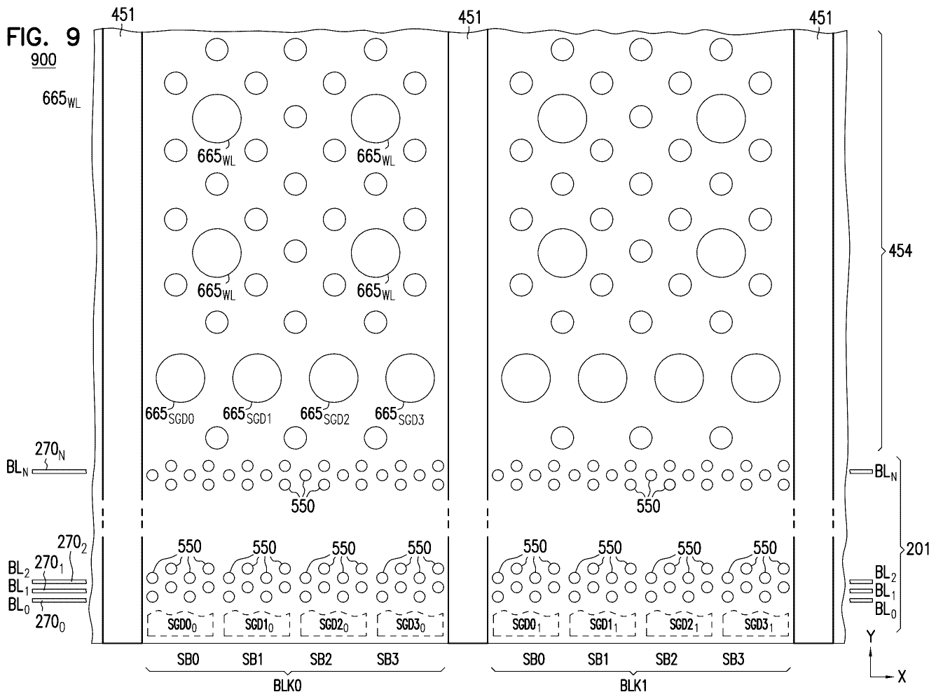

FIG. 9 shows a memory device 900 that can be a variation of memory device 200, according to some embodiments described herein. As show in FIG. 9 and FIG. 6A, memory device 900 can include elements that are similar to or the same as the elements of memory device 200. For simplicity, descriptions of similar or the same elements between memory devices 200 and 900 are not repeated. In comparison with memory device 200 (FIG. 6A), memory device 900 (FIG. 9) can include a higher number of conductive contacts (e.g., conductive contacts 665_{WL}) in region 454. For example, as shown in FIG. 9, memory device 900 can include multiple (e.g., two are shown as an example) conductive contacts 665_{WL} in region 454 that may be formed (e.g., formed in respective rows) in the X-direction. In the example of FIG. 9, multiple conductive contacts 665_{WL} (e.g., conductive contacts in the same row in the X-direction) can be coupled to (can contact) the same control gate. Alternatively, multiple conductive contacts (e.g., conductive contacts in the same row in the X-direction) can be coupled to (can contact) different control gates.

The above description with reference to FIG. 2 through FIG. 9 describes the structure of memory devices 200 and 900. Some or all of the structure of memory devices 200 and 900 can be formed using processes associated with the processes described below with reference to FIG. 10A through FIG. 39.

FIG. 10A through FIG. 29B show different views of elements during processes of forming a memory device 1000, according to some embodiments described herein. FIG. 10A shows a side view (e.g., cross-section) in the Y-direction of a portion of memory device 1000. FIG. 10B shows a side view (e.g., cross-section) in the X-direction (e.g., perpendicular to the Y-direction) of a portion of memory device 1000. FIG. 10C shows the locations of the side views of memory device 1000 of FIG. 10A and FIG. 10C that are taken along lines 10A and 10B, respectively, of FIG. 10C. Line 10A in FIG. 10C is similar to part of line 7 of FIG. 6A and FIG. 6B.

In FIG. 10C, the region included in memory array 201′ is similar to the region included in memory array 201 of memory device 200 in FIG. 6A. Region 454′ in FIG. 10C is similar to region 454 of memory device 200 in FIG. 6A. In FIG. 10C, regions (e.g., slit regions) 451′ can be similar to the regions of structures 451 (FIG. 4) of memory device 200.

In FIG. 10A and FIG. 10B, the process of forming memory device 1000 can include forming a material 1090 over substrate 1099. Material 1090 can form part of a source (e.g., associated with signal SRC) that is similar to source 290 of FIG. 7. Substrate 1099 is similar to (e.g., can correspond to) substrate 599 (FIG. 7) of memory device 200.

The processes associated with FIG. 10A and FIG. 10B include forming dielectric materials (levels of dielectric materials) 1021 and dielectric materials (levels of dielectric materials) 1022 over substrate 1099 (e.g., over material 1090). Dielectric materials 1021 can include silicon dioxide. Dielectric materials 1022 can include silicon nitride. Dielectric materials 1021 and 1022 can be sequentially formed one material after another over substrate 1099 in an interleaved fashion, such that dielectric materials 1021 can be interleaved with dielectric materials 1022. A dielectric material 1023 may also be formed over the interleaved dielectric materials 1021 and 1022.

As shown in FIG. 10A, dielectric materials 1021 and 1022 can form tiers (tiers of materials) 1025. Tiers 1025 are located one over another in the Z-direction. Each tier 1025 can include a respective level of dielectric material 1021 and a respective level of dielectric material 1022.

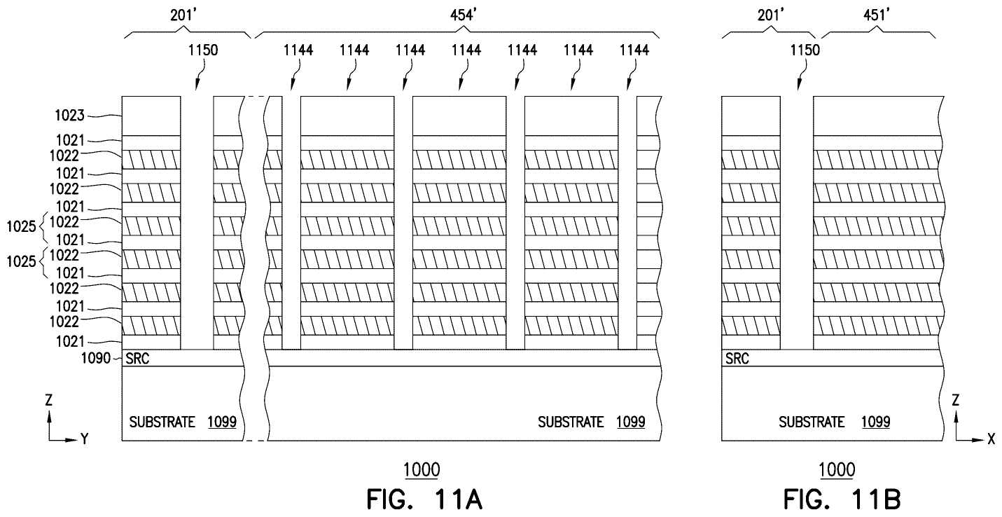

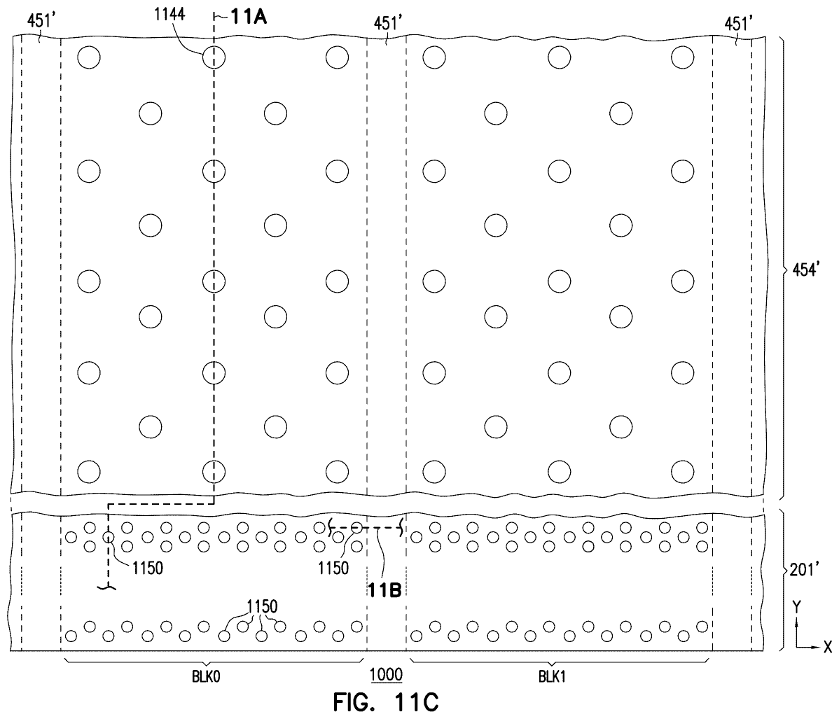

FIG. 11A, FIG. 11B, and FIG. 11C show memory device 1000 after openings (e.g., holes) 1150 and 1144 are formed. Forming openings 1150 and 1144 can include removing a portion of dielectric material 1023 and dielectric materials 1021 and 1022 at the locations of contact openings 1150 and 1144.

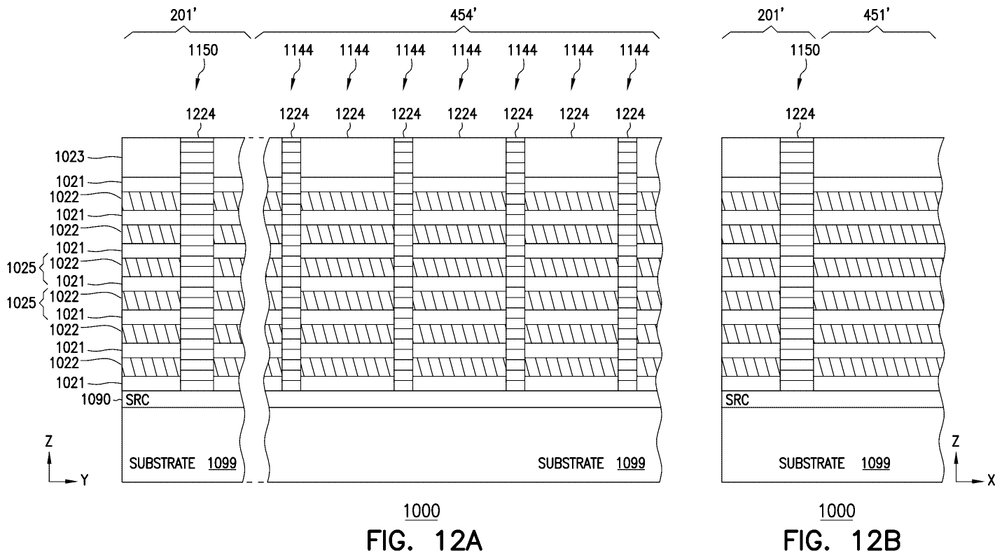

For simplicity, a top view (e.g., like FIG. 10C and FIG. 11C) of memory device 1000 are omitted from subsequent processes of forming a memory device 1000 associated with FIG. 12A through FIG. 29B.

FIG. 12A and FIG. 12B show memory device 1000 after a material (or materials) 1224 is formed (e.g., filled) in openings 1150 and 1144. In subsequent processes of forming memory device 1000, material 1224 can be removed (e.g., at different times) from openings 1150 and 1144. Thus, material 1224 can be called a sacrificial material. An example of material 1224 can include carbon or other materials. Forming material 1224 can include forming a material (e.g., carbon) in openings 1150 and 1144. A chemical mechanical polishing (CMP) process can be performed after material 1224 is formed.

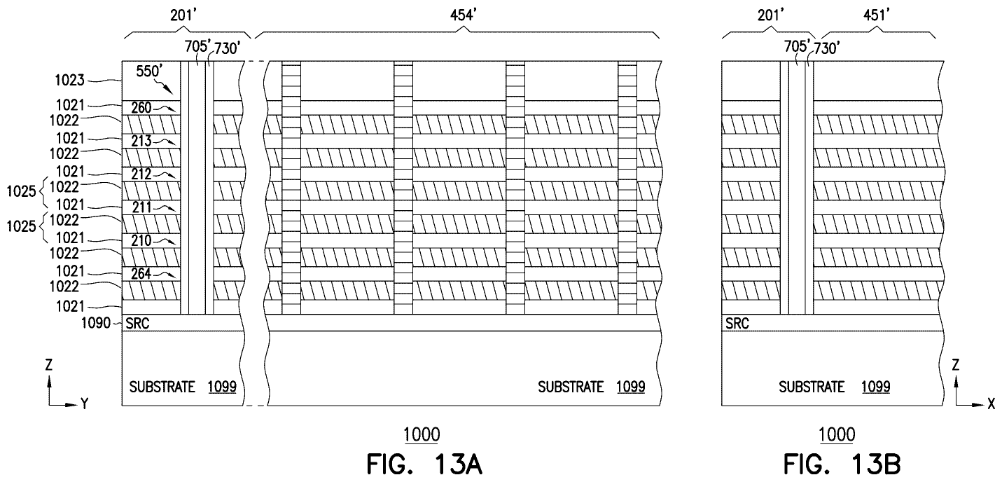

FIG. 13A and FIG. 13B show memory device 1000 after pillars (memory cell pillars) 550′ including structure 730′ and a dielectric material 705′ are formed. Pillars 550′, structure 730′, and dielectric material 705′ are similar to (e.g., can correspond to) pillars 550, structure 730, and dielectric material 705 of memory device 200 of FIG. 7. Forming pillars 550′ can include removing (exhuming) material 1224 from openings 1150 in the region of memory cell array 201′, and forming pillars 550′ (which include structure 730′ and dielectric material 705′) in the locations of openings 1150 (labeled in FIG. 11A and FIG. 11B). Material 1224 in openings 1144 (in region 454′) can remain (not be removed) during the processes associated with FIG. 13A and FIG. 13B. Similar to pillar 550 (FIG. 7), each pillar 550′ of FIG. 13A and FIG. 13B can include select gates 260 and 264 and memory cells (e.g., like memory cells 210, 211 212, and 213 in FIG. 7) of a respective memory cell string.

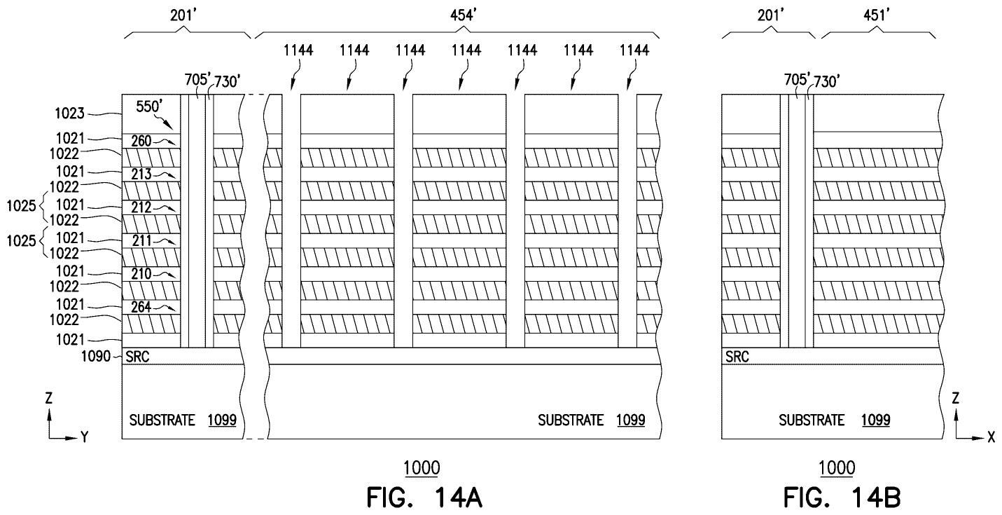

FIG. 14A and FIG. 14B show memory device 1000 after material 1224 (labeled in FIG. 12A and FIG. 12B) is removed (e.g., exhumed) from openings 1144.

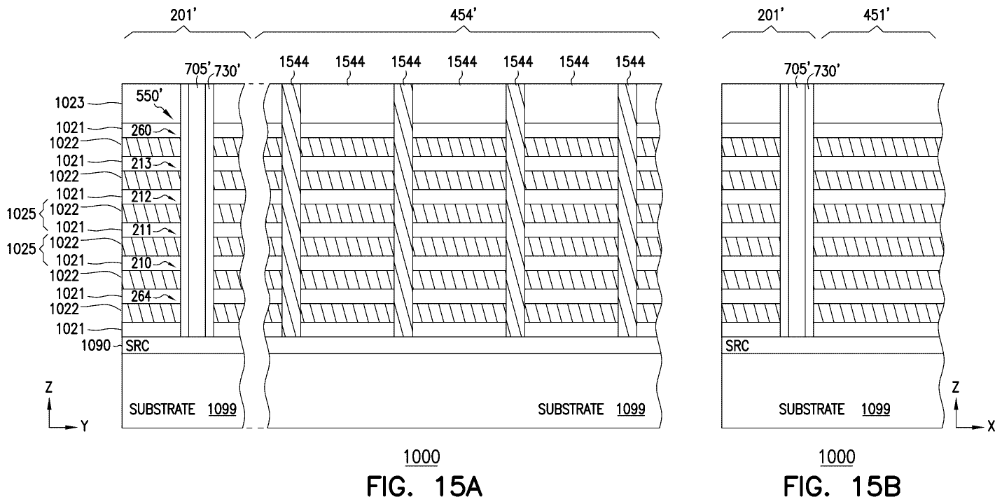

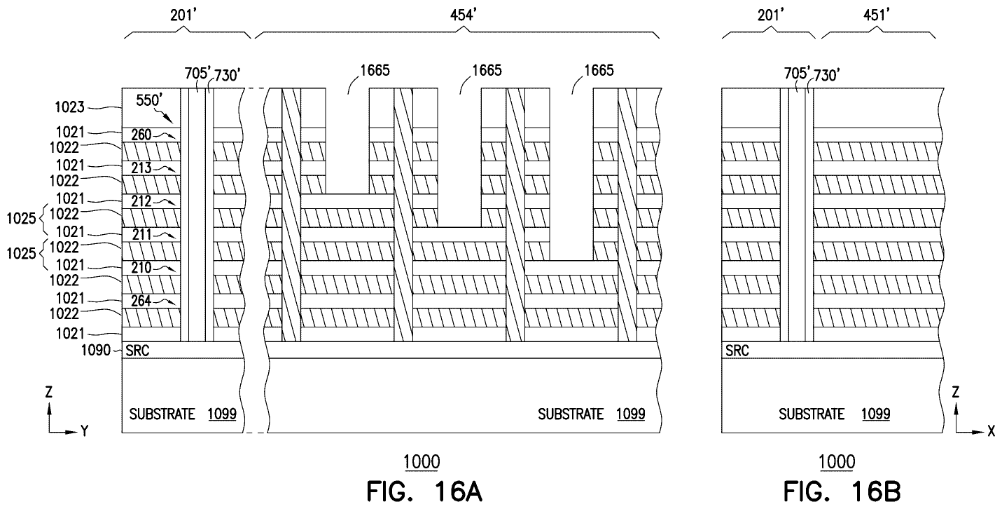

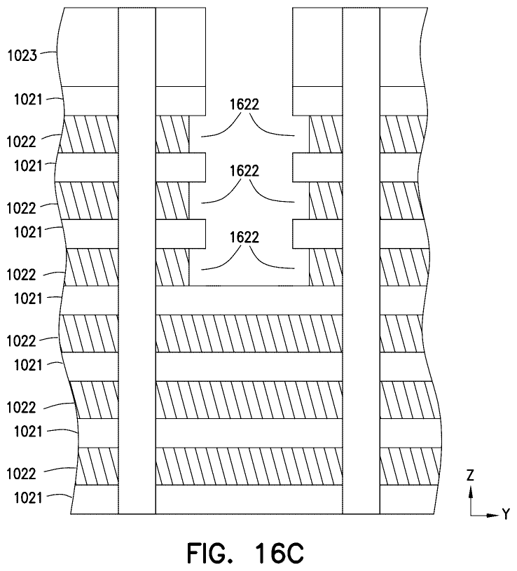

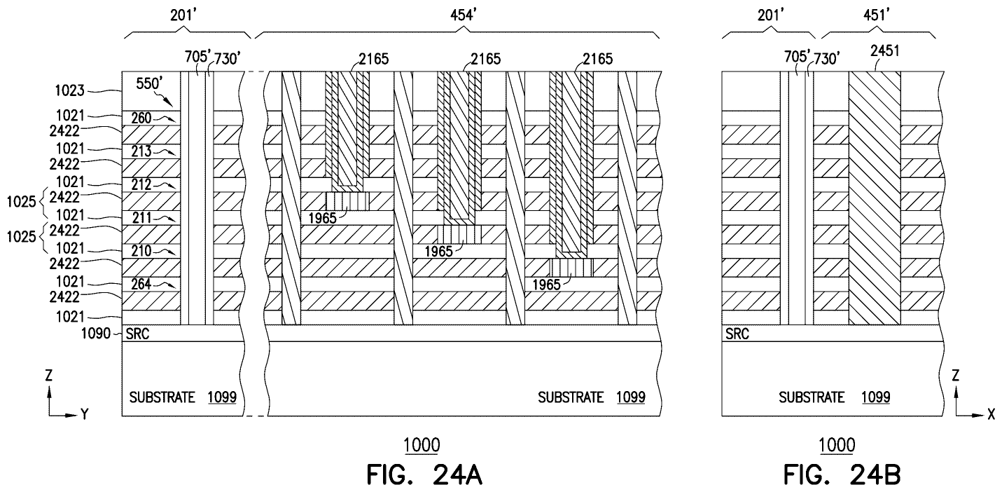

FIG. 15A and FIG. 15B show memory device 1000 after dielectric structures 1544 are formed in openings 1144 (labeled in FIG. 14A). Forming dielectric structures 1544 can include forming (e.g., filling) a dielectric material in openings 1144. An example of the dielectric material of dielectric structures 1544 can include silicon dioxide. Alternatively, the dielectric material of dielectric structures 1544 can include a material (e.g., different from silicon dioxide) that can be less susceptible to be removed (e.g., etched slower than dielectric materials 1021 and 1022) during processes associated with FIG. 16A in which a portion of dielectric materials 1021 and 1022 is removed (to form contact openings 1665). This allows the dielectric material (or a majority of the dielectric material) of dielectric structures 1544 to remain in memory device 1000 during the processes associated with FIG. 16A in which a portion of dielectric materials 1021 and 1022 is removed (to form contact openings 1665 in FIG. 16A). Further, the dielectric material of dielectric structures 1544 (FIG. 15) can include a material (e.g., different from silicon dioxide) that can remain in memory device 1000 during the processes associated with FIG. 24A in which dielectric materials 1022 are removed (to be replaced with a conductive material that forms control gates associated with memory cells 210, 211, 212, and 213).

FIG. 16A and FIG. 16B show memory device 1000 after contact openings 1665 are formed. Forming contact openings 1665 can include removing a portion of dielectric materials 1021 and 1022 at the locations of contact openings 1665. For simplicity, FIG. 16A shows a simple shape of openings 1665. However, the shape of openings 1665 is shown in more detail in FIG. 16C.

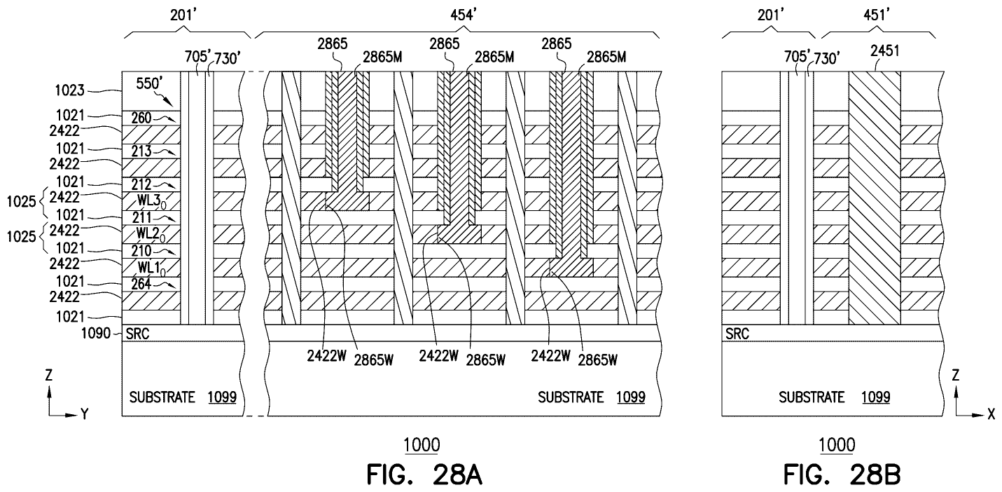

FIG. 16C shows an enlarged portion of an opening 1665 of FIG. 16. As shown in FIG. 16C, forming contact openings 1665 also includes removing respective portions of materials (e.g., silicon nitride) at locations 1622, such that part of openings 1665 (e.g., side walls of openings) can have the profile (e.g., shape) as shown in FIG. 16C. In FIG. 16C, removing respective portion of materials (e.g., silicon nitride) at locations 1622 can increase the effective width of dielectric isolation from one conductive contact to another conductive contact (e.g., conductive contacts 2865 (FIG. 28A) contacting respective levels of conductive materials 2422 that form part of the control gates (associated with signals WL1₀, WL2₀, and WL3₀) of memory device 1000.

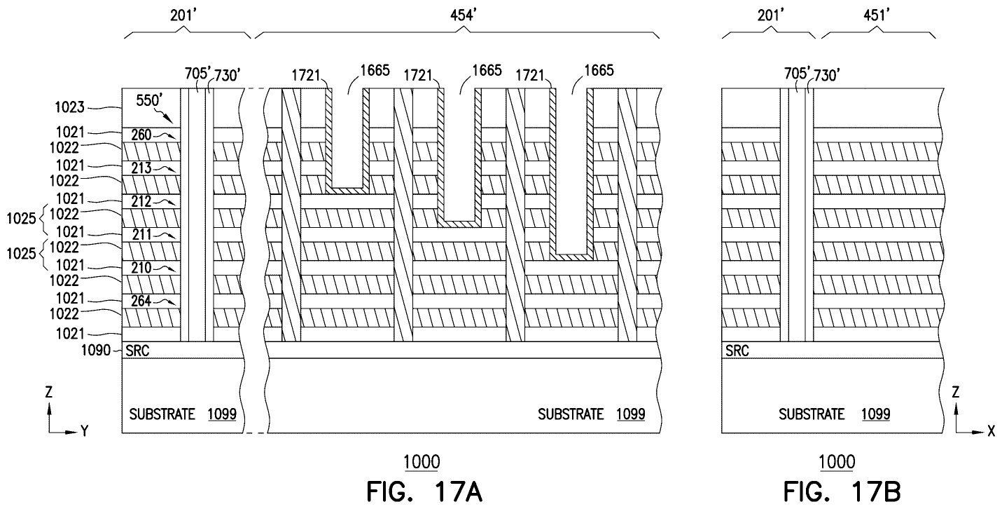

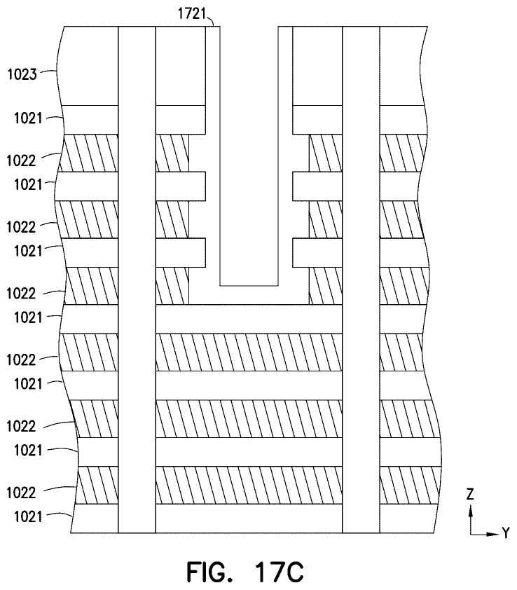

FIG. 17A and FIG. 17B show memory device 1000 after liners (dielectric liners) 1721 are formed in contact openings 1665. Forming liners 1721 can including forming a dielectric material (e.g., silicon dioxide) in contact openings 1665. The dielectric material can be relatively thin that covers side walls and bottoms of contact openings 1665 (as shown in FIG. 17A). FIG. 17C shows an enlarged portion of liners 1721 of FIG. 17A.

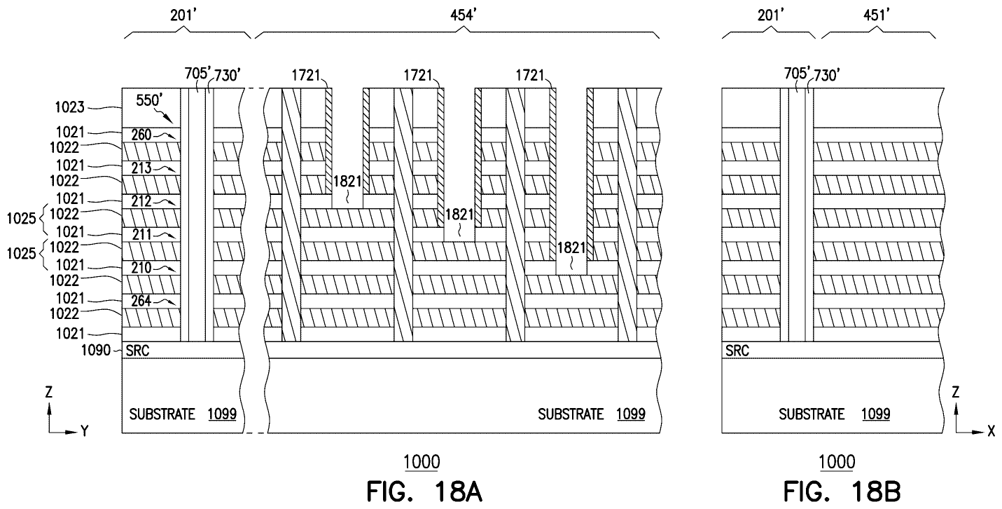

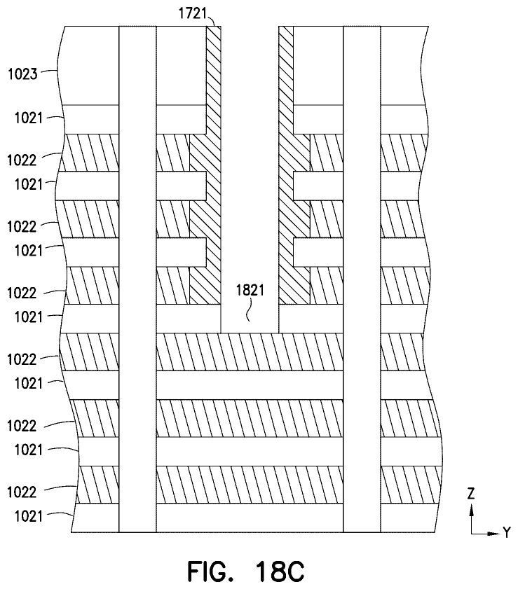

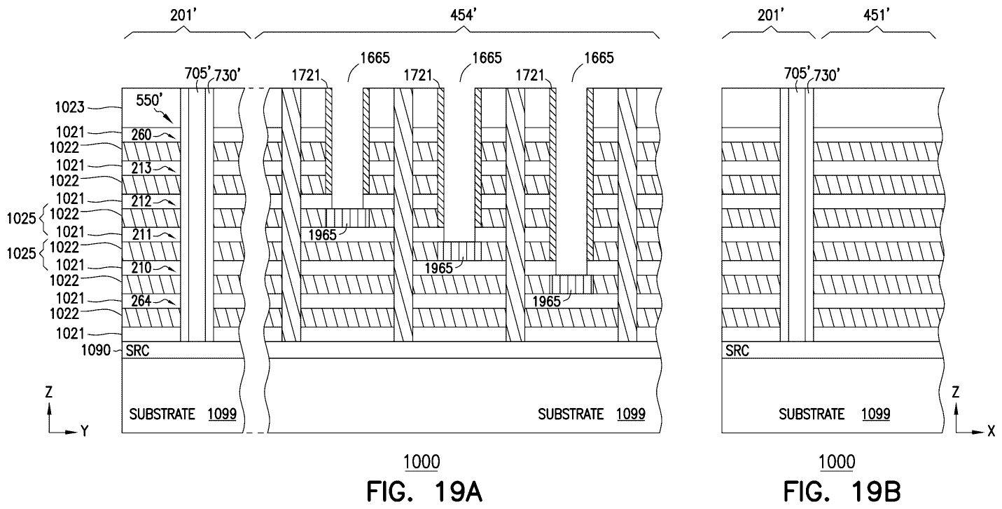

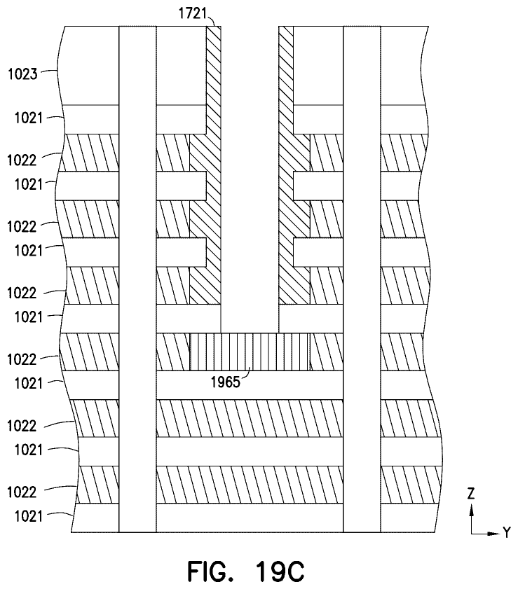

FIG. 18A and FIG. 18B show memory device 1000 after a portion (e.g., bottom portion) of liners 1721 at locations 1821 are removed (e.g., punch through). FIG. 18C shows an enlarged portion of liners 1721 of FIG. 18A after respective portions of liners 1721 are removed. FIG. 18A shows an example where liners 1721 are removed, such that respective levels of materials 1022 are exposed at locations 1821. However, in the processes associated with FIG. 18A and FIG. 18B, a portion of liners 1721 is removed, such that respective levels of dielectric materials 1022 may still be covered (not exposed) by respective dielectric materials 1021 at locations 1821. As described below with reference to FIG. 19A and FIG. 19B, structures 1965 can be formed at locations in respective levels of dielectric materials 1022 after portions of liners 1721 at locations 1821 are removed.

FIG. 19A and FIG. 19B show memory device 1000 after structures 1965 are formed in respective levels of dielectric materials 1022 at locations 1821. Structures 1965 can be formed such that the materials of structures 1965 are different from dielectric materials 1022. This allows structures 1965 to remain at their relative locations (shown in FIG. 19A) when dielectric materials 1022 are removed, as described below with reference to FIG. 24A and FIG. 24B. FIG. 19C shows an enlarged portion of memory device 1000 of FIG. 19A including structure 1965. An example material of structures 1965 can include carbon nitride or other material (or materials different from dielectric materials 1022).

An example of forming structures 1965 can include introducing (e.g., placing) a material into dielectric materials 1022 at locations 1821, such that materials (e.g., silicon nitride) 1022 at locations 1821 become different materials. For example, forming structures 1965 can include performing a process (e.g., vapor phase doping, selective etch or deposition, implantation, or other techniques) to introduce a material into dielectric materials 1022 at locations 1821 to form structures 1965, such that structures 1965 can include a material that is different from the material (e.g., silicon nitride) of dielectric materials 1022.

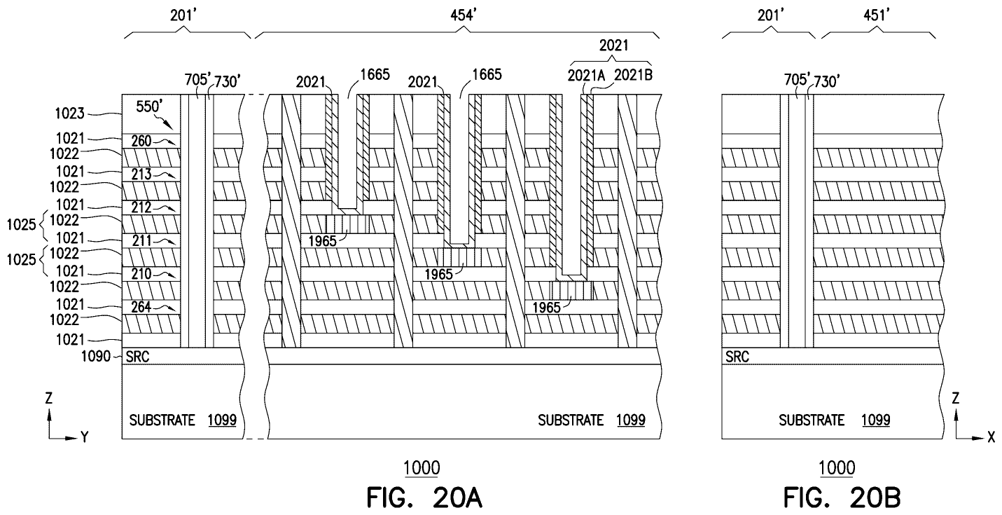

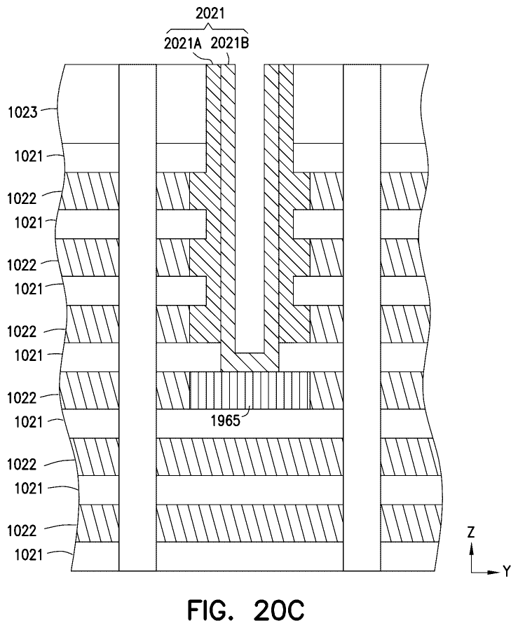

FIG. 20A and FIG. 20B show memory device 1000 after liners (dielectric liners) 2021 are formed in contact openings 1665. FIG. 20C shows an enlarged portion of memory device 1000 of FIG. 20A including liner 2021. Forming liners 2021 can including forming a dielectric material (e.g., silicon dioxide) in contact openings 1665 over liners 1721 (formed in FIG. 17) and over structure 1965. As shown in FIG. 20A, liner 2021 can include a portion 2021A and a portion 2021B adjacent portion 2021A. Portion 2021A can include the material (e.g., silicon dioxide) of liner 1721 (formed in FIG. 17). Portion 2021B can include the material (e.g., silicon dioxide) of liner 2021 that is formed in FIG. 20. Liner 2021 (which includes portions 2021A and 2021B) can be called a dielectric liner structure.

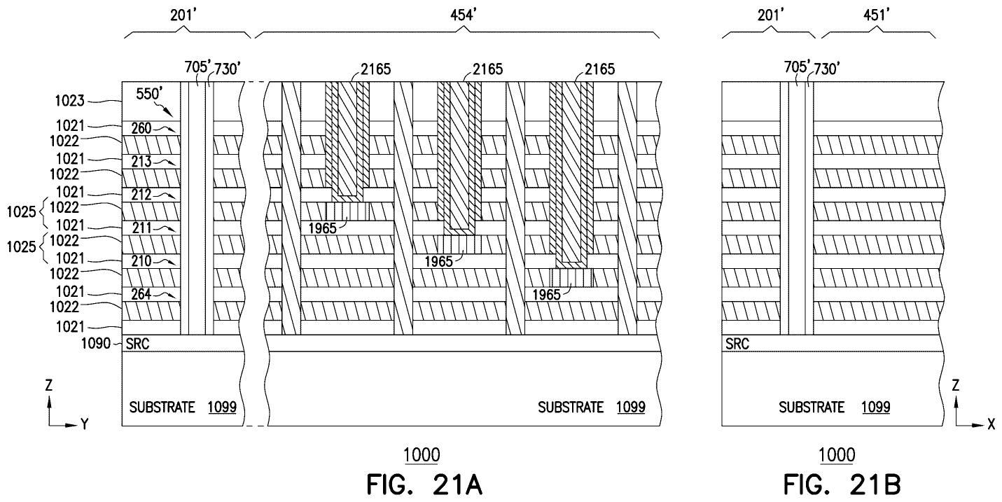

FIG. 21A and FIG. 21B show memory device 1000 after a material (e.g., a dielectric material) 2165 is formed (e.g., filled) in contact openings 1165 (labeled in FIG. 16). In subsequent processes of forming memory device 1000, material 2165 can be removed from openings 1665. Thus, material 2165 can be called a sacrificial material. A CMP process can be performed after material 2165 is formed.

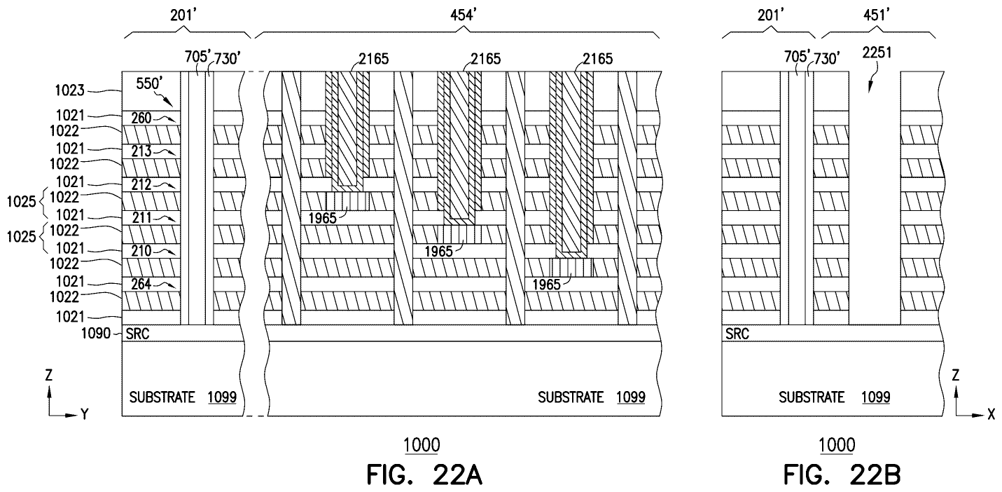

FIG. 22A and FIG. 22B show memory device 1000 after a slit (e.g., a trench) 2251 is formed at region 451′. Forming slit 2251 can include removing a portion of dielectric material 1023, and a portion of dielectric materials 1021 and 1022 at the location of slit 2251.

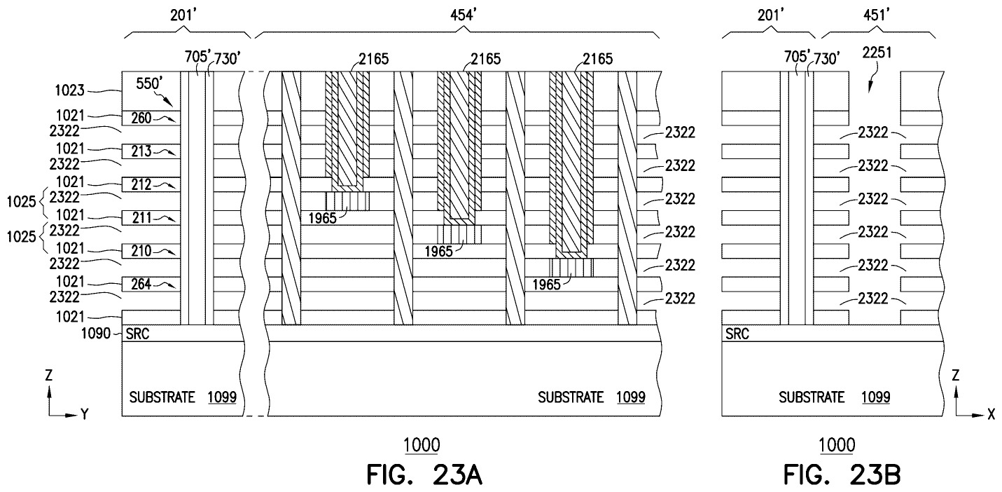

FIG. 23A and FIG. 23B show memory device 1000 after dielectric materials 1022 (FIG. 22A) are removed (e.g., exhumed) from locations 2322. Locations 2322 in FIG. 23A and FIG. 23B are voids (empty spaces) that were occupied by dielectric materials 1022. In subsequent processes, conductive materials can be formed in locations 2322 to form respective control gates of memory device 1000.

FIG. 24A and FIG. 24B show memory device 1000 after conductive materials (levels of conductive materials) 2422 are formed in locations 2022 (FIG. 23). Conductive materials 2422 are sometimes called levels of conductive materials 2422. Conductive materials 2422 can form part of the control gates and select lines of memory device 1000 that can be similar to the control gates associated with signals associated with signals WL0₀, WL1₀, WL2₀, and WL3₀ (FIG. 7) of memory device 200 (FIG. 7) and the select line associated with signal SGD0₀ and SGD₀ (FIG. 7) of memory device 200. FIG. 24A and FIG. 24B show an example where some of the levels of conductive materials 2422 can form the control gates (e.g., the control gates similar to control gates associated with signals WL1₀, WL2₀, and WL3₀ of memory device 200 of FIG. 7) of memory device 1000. Thus, forming conductive materials 2422 includes forming the control gates and select lines of memory device 1000.

In FIG. 24A and FIG. 24B, forming conductive materials 2422 can include forming (e.g., filling) a conductive material (or a combination of conductive materials) 2422 in locations 2322 (FIG. 23A). As described above, locations 2322 are locations of dielectric materials 1022 (FIG. 22A) that were removed in FIG. 23. Thus, in FIG. 24, forming the control gates (e.g., the control gates associated with signals WL0₀, WL1₀, and WL3₀) and the select lines of memory device 1000 can include replacing the levels of dielectric materials 1022 (FIG. 23A) with respective levels of conductive materials 2422 (FIG. 24A). Conductive materials 2422 can include a similar material or the same material as conductive materials 522 (FIG. 7) of memory device 230. Thus, conductive materials 2422 can include a single conductive material (e.g., single metal (e.g., tungsten)) or a combination of different layers of conductive materials. For example, conductive material 2422 can include (e.g., can have multi-layers of) aluminum oxide, titanium nitride, and tungsten, or other conductive materials.

As shown in FIG. 24B, a structure 2451 is formed in slit 2251 (labeled in FIG. 23B). Structure 2451 can be similar to structure 451 (FIG. 4) of memory device 230. Forming structure 2451 can include forming (e.g., filling) a material (or materials) in slit 2251. Example materials of structure 2451 include a dielectric material (e.g., silicon oxide) or other materials.

FIG. 25A and FIG. 25B show memory device 1000 after material 2165 (labeled in FIG. 24A) is removed (e.g., exhumed) from contact openings 1665.

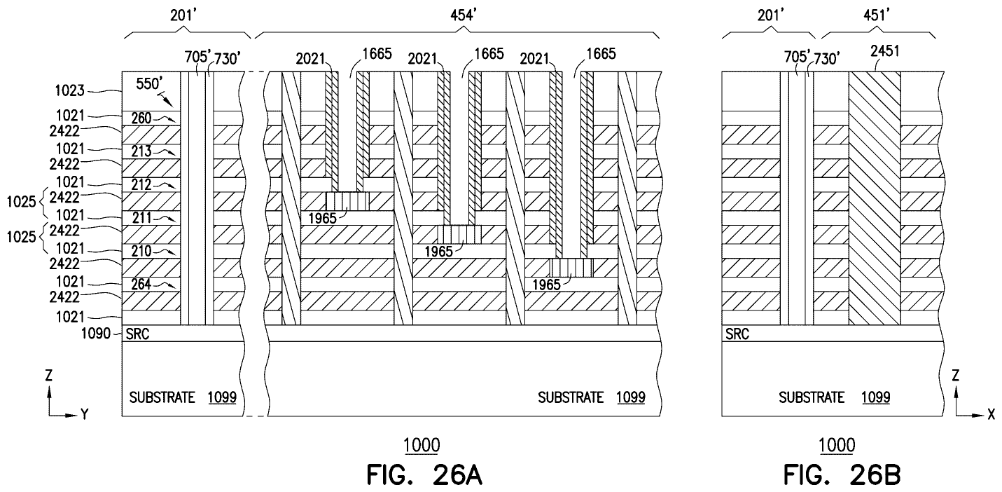

FIG. 26A and FIG. 26B show memory device 1000 after a portion (e.g., bottom portion) of liners 2021 is removed (e.g., punch through). As shown in FIG. 22A, structures 1965 are exposed at contact openings 1665 at the locations where the portions of liners 2021 were removed.

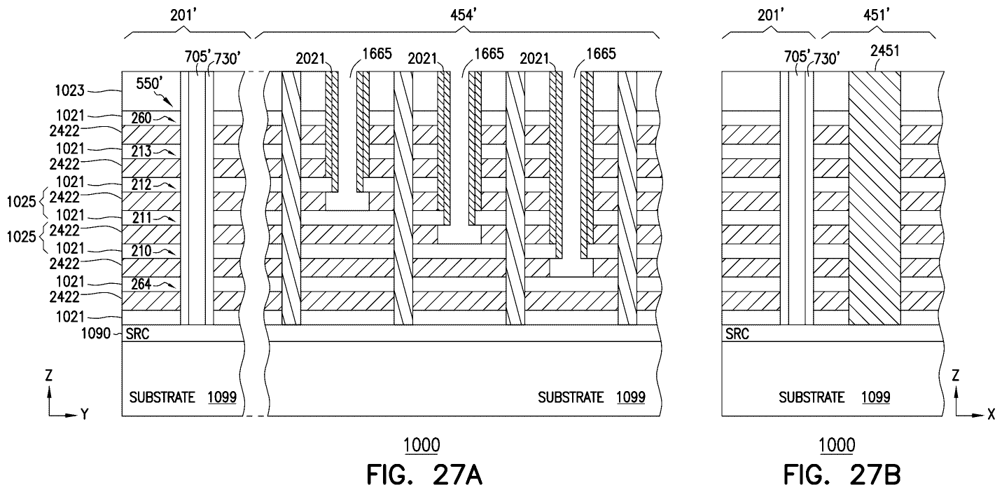

FIG. 27A and FIG. 27B show memory device 1000 after structures 1965 (FIG. 26A) are removed.

FIG. 28A and FIG. 28B show memory device 1000 after conductive contacts 2865 are formed in contact openings 1665 (labeled in FIG. 23A). As shown in FIG. 28A, some of the levels of conductive materials 2422 can form part of respective control gates (e.g., the control gates associated with signals WL1₀, WL2₀, and WL3₀) of memory device 1000. As shown in FIG. 28A, conductive contacts 2865 can include respective side walls 2865W (having the height in the Z-direction) adjacent (e.g., contacting) respective side walls 2422W (having the height in the Z-direction) of respective levels of conductive materials 2422. Forming conductive contacts 2865 can include forming (e.g., filling) a conductive material 2865M in contact openings 1665. Conductive material 2865M and conductive material 2422 can be similar to (or the same as) conductive material 665M and conductive material 522, respectively.

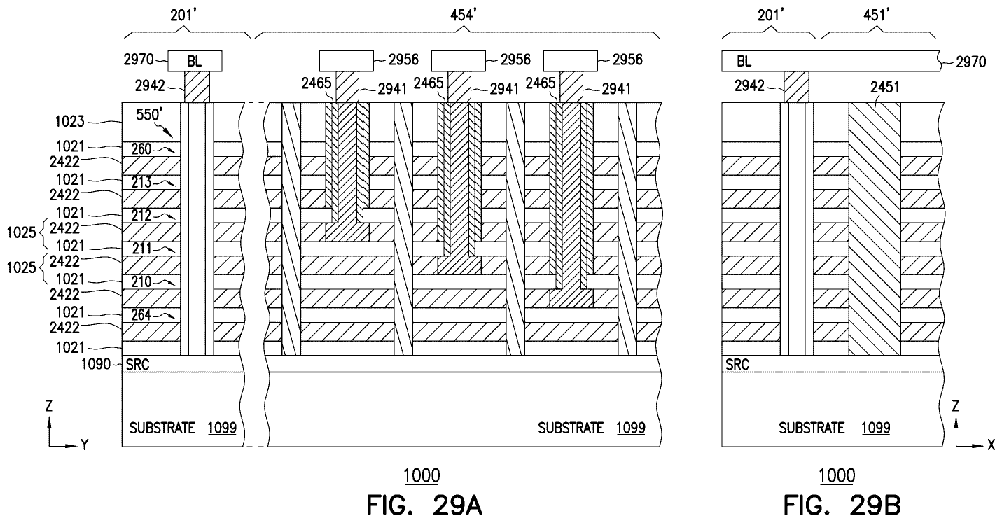

FIG. 29A and FIG. 29B show memory device 1000 after conductive portions 2941 and 2942, data lines 2970, and conductive lines 2956 are formed. Data lines 2970 and signals BL can be similar to data lines 270₀ through 270_{N} and signals BL₀ through BL_{N}, respectively, of memory device 200 in FIG. 4. Conductive lines 2956 can be similar to conductive lines 656 of FIG. 6C. Thus, conductive lines 2956 can have respective lengths in the X-direction.

Conductive portions 2942 can be coupled to respective data lines 2970 (associated with signals BL) and respective pillars (memory cell pillars) 550. Conductive portions 2941 can be coupled to respective conductive lines 2956 and respective conductive contacts 2465. Conductive portions 2941 can be similar to conductive portions 641 of memory device of FIG. 6C.

The processes of forming memory device 1000 described above with reference to FIG. 10A through FIG. 29B can include other processes to form a complete memory device (e.g., memory device 1000). Such processes are omitted from the above description so as not to obscure the subject matter described herein.

Forming memory device 1000 as described above can provide improvements and benefits to memory device 1000 in comparison to some conventional techniques. For example, forming structures 1965 (FIG. 19A) can prevent the region (e.g., region that includes conductive contacts 2865) from damage (e.g., collapse) during the processes of forming memory device 1000. Further, forming structures 1965 (FIG. 19A) can be viewed as providing treatment to tiers 1025 at the locations in tiers 1025 where structures 1965 were formed. The treated tiers (e.g., tier 1025 treated at the locations of structures 1965) can improve the quality of conductive contacts 2865 formed in the treated tiers at the locations of structures 1965. Improved quality can lead to improved contact (e.g., at side walls 2422W and 2865W) between conductive contacts and respective levels of conductive materials 2422 (FIG. 28A). This can lead to improved operations that involve conductive contacts and respective levels of conductive materials 242.

Moreover, as described above, memory device 200 can be formed using processes similar to the processes of forming memory device 1000. Thus, as shown in FIG. 7 and FIG. 8C, the structure of memory device 200 at conductive contacts 665_{WL} and levels of conductive materials 522 (e.g., in tiers 525 (e.g., treated tiers) in FIG. 7) is similar to the structure of memory device 200 at conductive contacts 665_{WL} and levels of conductive materials 2422 (e.g., in tier 1025 (e.g., treated tiers) in FIG. 28A). There, memory device 700 can also include improvements and benefits similar to those of memory device 1000.

The structure and processes (including tier treatment described herein) associated with forming memory device 1000 can lead to improvement in at least one of yield, cost, performance, and reliability of memory device 1000 and other memory devices (e.g., memory devices 200, 900, 1000, 3000, 3300, and 3400) described herein.

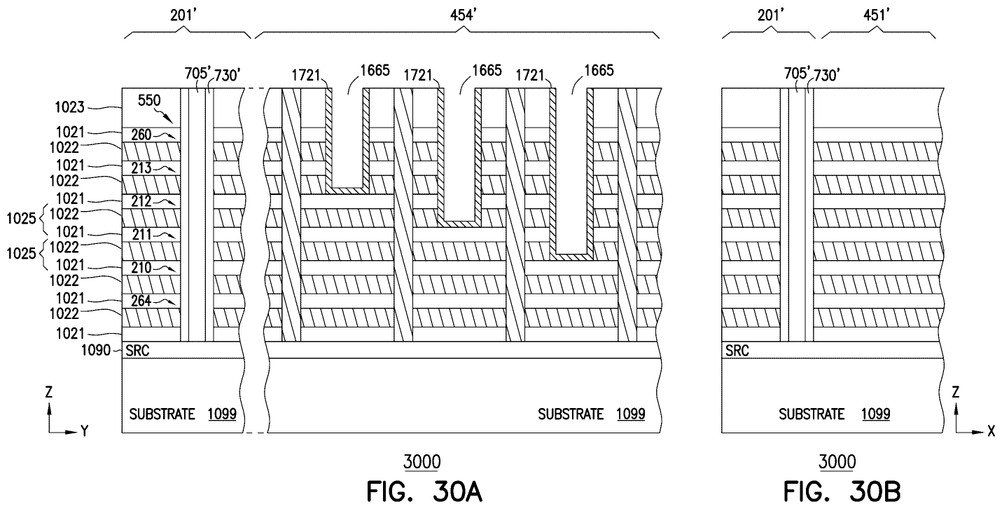

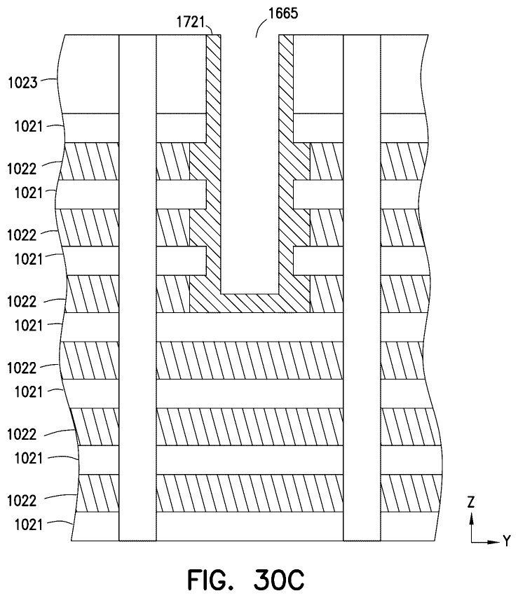

FIG. 30A through FIG. 32B show different views of elements during processes of forming memory device 3000, according to some embodiments described herein. The processes of forming memory device 3000 can be similar to or the same as the processes of forming memory device 1000 (FIG. 10A through FIG. 29B). Some of the processes of forming memory device 3000 (FIG. 30A through FIG. 32B) are similar to or the same as processes of forming memory device 1000 (FIG. 10A through FIG. 29B). Thus, for simplicity, similar or the same process are not repeated.

FIG. 30A, FIG. 30B, and FIG. 30C show elements of memory device 3000 that are the same as those of memory device 1000 shown in FIG. 17A, FIG. 17B, and FIG. 17C.

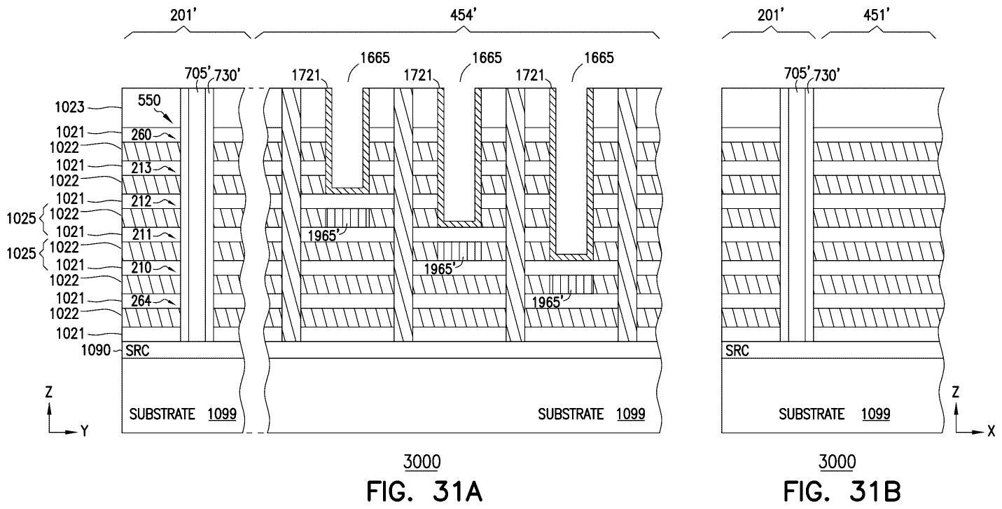

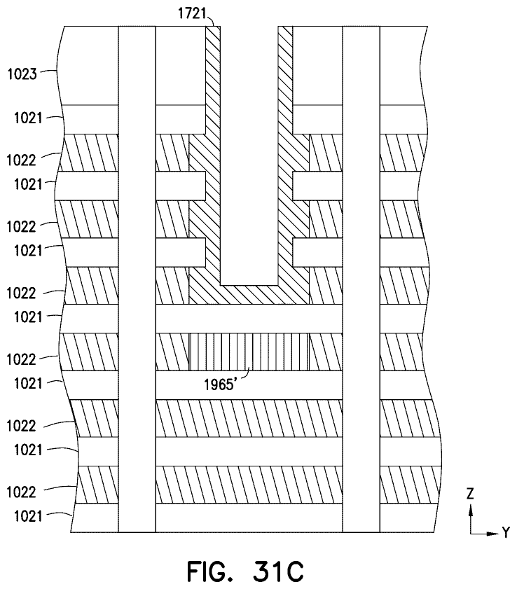

FIG. 31A and FIG. 31B show memory device 3000 after structures 1965′ are formed in respective levels of dielectric materials 1022. Structures 1965′ are similar to or the same as structures 1965 of FIG. 19A and can be formed using processes associated with FIG. 19A and FIG. 19B. FIG. 31C shows an enlarged portion of memory device 3000 of FIG. 31A including structure 1965′.

The processes of forming memory device 3000 from FIG. 30A and FIG. 30B to FIG. 31A and FIG. 31B can omit (skip) the processes associated with FIG. 18A and FIG. 18B, and FIG. 20A and FIG. 20B. Thus, unlike FIG. 18A, a portion (e.g., bottom portion) of liner 1721 in FIG. 30A is not removed before forming structure 1965′ in FIG. 31A. However, after forming structure 1965′, a portion (e.g., bottom portion) of liners 1721 of FIG. 31A is removed (e.g., punch through) in a subsequent process that is similar to removing a portion (e.g., bottom portion) of liners 2021 in FIG. 26A in the processes of forming memory device 1000. Since a portion (e.g., bottom portion) of liner 1721 in FIG. 30A is not removed, forming liner 2021 (forming portion 2021B) in FIG. 20A can be omitted (skipped) in the processes of forming memory device 3000.

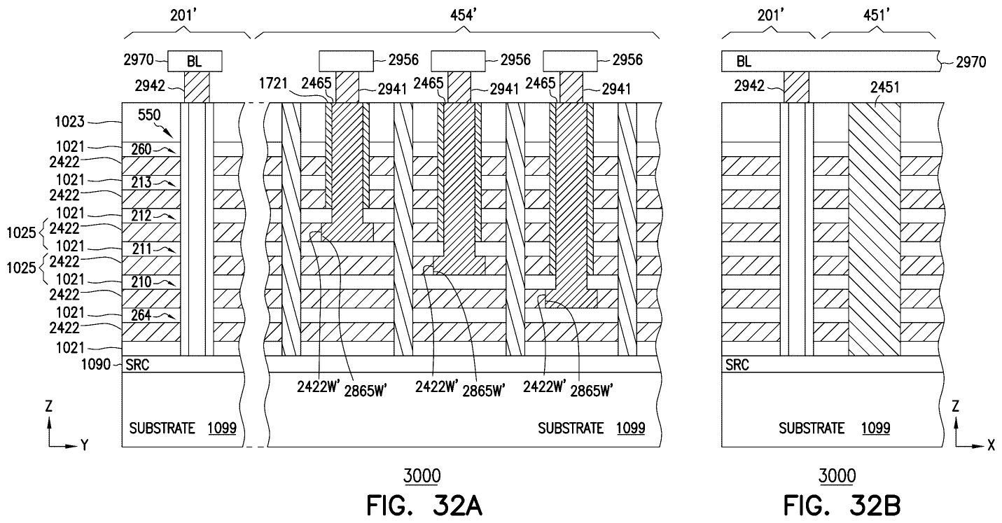

The processes of forming memory device 3000 can continue from FIGS. 32A and 32B and additional processes can be performed similar to the processes of forming memory device 1000 associated with shown in FIG. 21A through FIG. 29B.

FIG. 32A and FIG. 32B show memory device 3000 after other elements of memory device 3000 are formed. The elements of memory device 3000 in FIG. 32A and FIG. 32B are similar to those of the elements of memory device 1000 of FIG. 29A and FIG. 29B. Thus, for simplicity, similar or the same elements between memory devices 1000 and 3000 are given the same labels. As shown in FIG. 32A and FIG. 32B, memory device 3000 can include side walls 2422W′ and 2865W′ that can be similar to side walls 2422W and 2865W, respectively, of memory device 1000 of FIG. 28A or side walls 522W and 665W, respectively, of memory device 200 of FIG. 8C. Improvements and benefits of memory device 3000 are similar to or the same as improvements and benefits of memory devices 200 and 1000 described above.

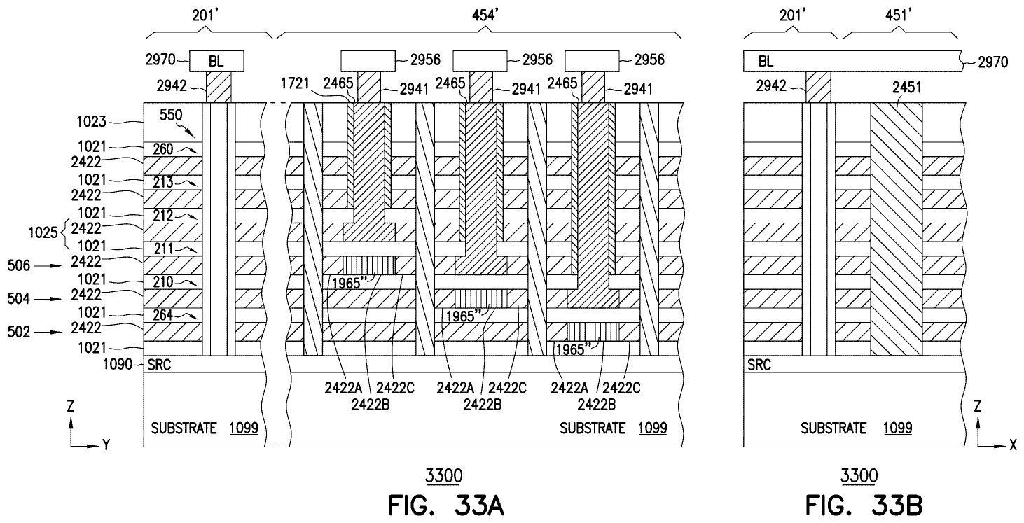

FIG. 33A and FIG. 33B show a memory device 3300, according to some embodiments described herein. Memory device 3300 can include elements similar to those of memory devices 1000 and 3300. Thus, memory device 3300 can be formed using processes similar to the processes of forming memory devices 1000 and 3300 described above with reference to FIG. 10A through FIG. 32B. Thus, for simplicity, detailed processes of forming memory device 3300 are not described herein.

FIG. 33A shows levels of conductive materials 2422 located in the respective levels (e.g., levels 504, 506, and 508) of memory device 3300. As shown in FIG. 33A, each of levels of conductive materials 2422 in respective levels 502, 504, and 506 can include a portion 2422A, 2422B, and 2422C, where portion 2422B is between portions 2422A and 2422C. Memory device 3300 can include structures 1965″ located in portions 2422B of respective levels of conductive materials 2422 in respective levels 502, 504, and 506. Structures 1965″ are similar to structures 1965 formed in the processes associated with forming memory device 1000 in FIG. 19A or structures 1965′ formed in the processes associated forming memory device 3000 in FIG. 31A. However, as shown in FIG. 33A, structures 1965″ remain in memory device 3300 (remain in the final structure of memory device 3300).

The processes of forming memory device 3400 including forming structures 1965″ are similar to processes of forming memory device 1000 (FIG. 10A through FIG. 29B) or processes of forming memory device 3000 (FIG. 30A through FIG. 32B). However, unlike the processes of forming memory devices 1000 and 3000, structures 1965″ are not removed from memory device 3300. Thus, the processes of forming memory device 3300 can skip the processes like the processes of removing structure 1965 associated FIG. 27A.

Further, unlike the processes of forming memory devices 1000 and 3000, structures 1965″ of memory device 3300 (FIG. 33A) can be formed in levels (e.g., levels 504, 506, and 508) that are below the levels where conductive contacts 2465 contact respective levels of conductive materials 2422. For example, the structures 1965″ on level 504 is one level below the conductive contact 2465 contacting the conductive materials on level 506. Improvements and benefits of memory device 3300 are similar to or the same as improvements and benefits of memory devices 200, 1000, and 3000 described above.

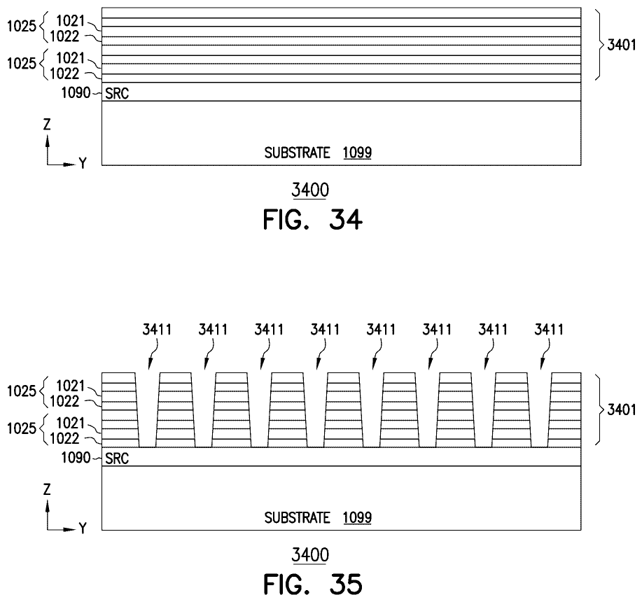

FIG. 34 through FIG. 39 show a side view of elements during processes of forming a memory device 3400 having multiple decks 3401, 3402, and 3403, according to some embodiments described herein. The processes of forming memory device 3400 can be similar to or the same as the processes of forming memory device 1000 (FIG. 10A through FIG. 29B) or the processes of forming memory device 3000 (FIG. 30A through FIG. 32B). Differences between the processes of forming a memory devices 1000, 3000, and 3400 include the processes of forming openings 3411, 3412, and 3413 (FIG. 34 through FIG. 39).

FIG. 34 shows memory device 3400 after dielectric materials 1021 and 1022 are formed in tiers 1025. Dielectric materials 1021 and 1022 can be included in deck 3401 of memory device 3400.

FIG. 35 shows memory device 3400 after openings (e.g., holes) 3411 are formed. Forming openings 3411 can include removing a portion of dielectric materials 1021 and 1022 of deck 3401 at the locations of openings 3411.

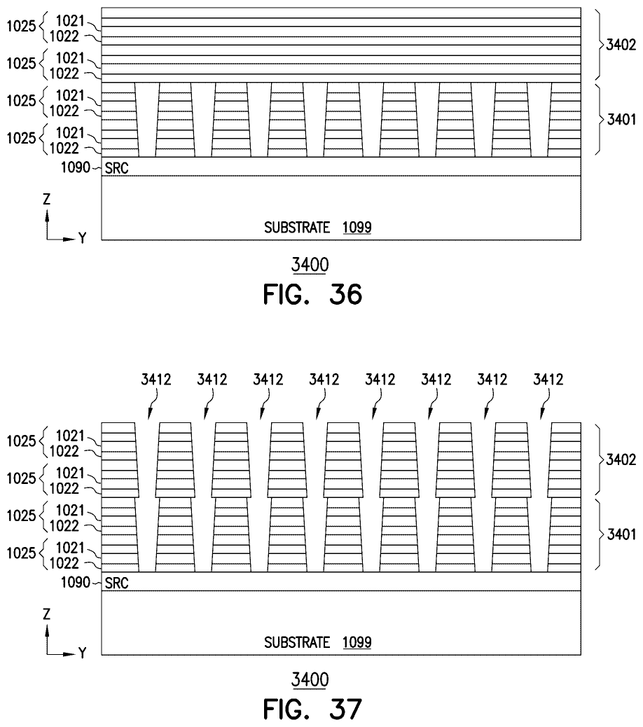

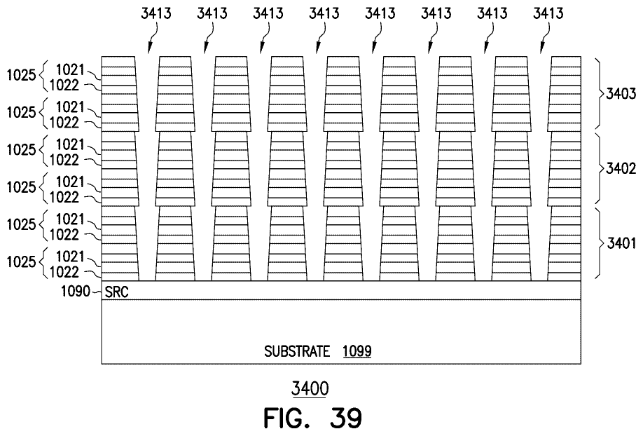

FIG. 36 shows memory device 3400 after dielectric materials 1021 and 1022 are formed in tiers 1025 included in deck 3402 of memory device 3400. The processes associated with FIG. 36 can include forming a sacrificial material (not shown) in openings 3411 before dielectric materials 1021 and 1022 of deck 3402 are formed. The sacrificial material can be subsequently removed (e.g., removed when openings 3413 in FIG. 39 are formed).

FIG. 37 shows memory device 3400 after openings (e.g., holes) 3412 are formed. Forming openings 3412 can include removing a portion of dielectric materials 1021 and 1022 of deck 3402 at the locations of openings 3412. As shown in FIG. 37, openings 3412 can be aligned (e.g., vertically aligned in the Z-direction) with respective openings 3411 formed in the processes associated with FIG. 31.

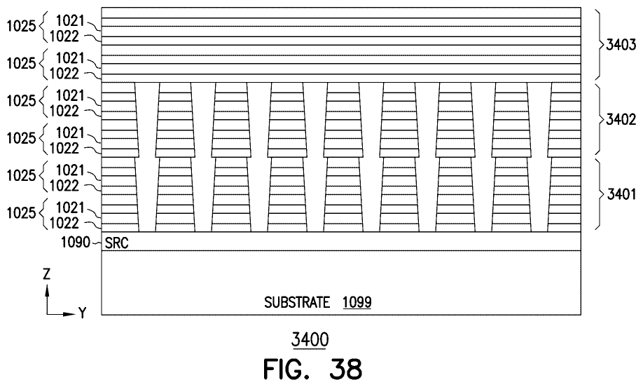

FIG. 38 shows memory device 3400 after dielectric materials 1021 and 1022 are formed in tiers 1025 included in deck 3403 of memory device 3400. The processes associated with FIG. 38 can include forming a sacrificial material (not shown) in openings 3412 before dielectric materials 1021 and 1022 of deck 3403 are formed. The sacrificial material can be subsequently removed (e.g., removed when openings 3413 in FIG. 39 are formed).

FIG. 39 shows memory device 3400 after openings (e.g., holes) 3413 are formed. Forming openings 3413 can include removing a portion of dielectric materials 1021 and 1022 of deck 3403 at the locations of openings 3413. Forming openings 3413 can also include removing sacrificial materials (not shown) in openings 3411 and 3412. As shown in FIG. 39, openings 3413 can be aligned (e.g., vertically aligned in the Z-direction) with respective openings 3411 and 3412 formed in the processes associated with FIG. 34 and FIG. 39.

The structure of memory device 3400 can be called a multi-deck structure (which includes decks 3401, 3402, and 3403). The process of forming memory device 3400 can continue with processes that are similar to or the same as the processes of forming memory device 1000 described above with reference to FIG. 11A through FIG. 29B. Thus, for simplicity, additional processes of forming memory device 3400 are omitted from the description herein. Improvements and benefits of memory device 3400 are similar to or the same as improvements and benefits of memory device 200 described above.

The combination of openings 3411, 3412, and 3413 (formed in the processes associated with FIG. 34 through FIG. 39) can be similar to openings 1144 and 1150 of FIG. 11A and FIG. 11B. In alternative processes of forming memory device 1000 (FIG. 10A through FIG. 29B), memory device 3000 (FIG. 30A through FIG. 32B), and memory device 3300 (FIG. 33A and FIG. 33B), the structure of memory devices 1000, 3000, and 3300 can include the structure (e.g., multi-deck structure) of memory device 3400 (FIG. 34 through FIG. 39). Thus, forming openings 1144 and 1150 (FIG. 11A and FIG. 11B) in the processes associated with forming memory devices 1000, 3000, and 3300 can include forming openings 3411, 3412, and 3413 described above with reference to FIG. 34 through FIG. 39.

The illustrations of apparatuses (e.g., memory devices 100, 200, 900, 1000, 3000, 3300, and 3400) and methods (e.g., method of forming memory devices 1000 and 3000) are intended to provide a general understanding of the structure of various embodiments and are not intended to provide a complete description of all the elements and features of apparatuses that might make use of the structures described herein. An apparatus herein refers to, for example, either a device (e.g., any of memory devices 100, 200, 900, 1000, 3000, 3300, and 3400) or a system (e.g., a computer, a cellular phone, or other electronic systems) that includes a device such as any of memory devices 100, 200, 900, 1000, 3000, 3300, and 3400.

Any of the components described above with reference to FIG. 1 through FIG. 39 can be implemented in a number of ways, including simulation via software. Thus, apparatuses, e.g., memory devices 100, 200, 900, 1000, 3000, 3300, and 3400 or part of each of these memory devices described above, may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

Memory devices 100, 200, 900, 1000, 3000, 3300, and 3400 may be included in apparatuses (e.g., electronic circuitry) such as high-speed computers, communication and signal processing circuitry, single- or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

The embodiments described above with reference to FIG. 1 through FIG. 39 include apparatuses and methods of forming the apparatuses. One of the apparatuses includes a memory device, which includes levels of dielectric materials; levels of conductive materials interleaved with the levels of dielectric materials, the levels of conductive materials including a first conductive level and a second conductive level; a memory cell string including a pillar extending in a direction from the first conductive level to the second conductive level, the second conductive level including a side wall; and a conductive contact extending in the direction from the first conductive level to the second conductive level, the conductive contact including a first portion separated from the first conductive level by a dielectric material, and a second portion adjacent the side wall of the second conductive level. Other embodiments including additional apparatuses and methods are described.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, the terms “first”, “second”, and “third,” etc. are used merely as labels, and are not intended to impose numerical requirements on their objects.

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

What is claimed is:

1. An apparatus comprising:
levels of dielectric materials;
levels of conductive materials interleaved with the levels of dielectric materials, the levels of conductive materials including a first conductive level and a second conductive level;
a memory cell string including a pillar extending in a direction from the first conductive level to the second conductive level, the second conductive level including a side wall;
a conductive contact extending in the direction from the first conductive level to the second conductive level, the conductive contact including a first portion separated from the first conductive level by a dielectric material, and a second portion adjacent the side wall of the second conductive level.

2. The apparatus of claim 1, further comprising an additional conductive contact extending in the direction from the first conductive level to the second conductive level, wherein the first conductive level includes a side wall, and the additional conductive contact includes a portion adjacent the side wall of the first conductive level.

3. The apparatus of claim 2, further comprising a dielectric pillar between the conductive contact and the additional conductive contact, the dielectric pillar extending in the direction from the first conductive level to the second conductive level.

4. The apparatus of claim 3, further comprising an additional dielectric pillar extending in the direction from the first conductive level to the second conductive level, wherein the additional conductive contact is between the dielectric pillar and the additional dielectric pillar.

5. The apparatus of claim 1, wherein:
the levels of conductive materials include a third conductive level, and the second conductive level is between the first conductive level and the third conductive level; and
the third conductive level includes a first portion, a second portion, and a third portion, the second portion being between the first portion and the third portion, wherein the second portion includes a material different from a material of each of the first portion and the third portion.

6. The apparatus of claim 1, wherein the second conductive level is part of a word line associated with the memory cell string.

7. The apparatus of claim 1, wherein the conductive contact includes a first conductive material contacting the side wall of the second conductive level, and a second conductive material adjacent the first conductive material.

8. The apparatus of claim 1, wherein the second conductive level includes a first conductive material contacting the conductive contact, and a second conductive material adjacent the first conductive material.

9. The apparatus of claim 1, wherein:
the conductive contact includes a first conductive material contacting the side wall of the second conductive level, and a second conductive material adjacent the first conductive material; and
the second conductive level includes a third conductive material contacting the first conductive material, wherein the first conductive material and the third conductive material include different materials.

10. The apparatus of claim 1, wherein:
the conductive contact includes a first conductive material contacting the side wall of the second conductive level; and
the second conductive level includes a second conductive material contacting the first conductive material, wherein the first conductive material and the second conductive material include different materials.

11. An apparatus comprising:
a first tier including first memory cells and a first control gate associated with the first memory cells;
a second tier including second memory cells and a second control gate associated with the second memory cells; and
a conductive contact extending in a direction from the first control gate to the second control gate, the conductive contact including a first portion separated from the first control gate by a dielectric material, and a second portion contacting a side wall of the second control gate.

12. The apparatus of claim 11, further comprising an additional conductive contact extending in the direction from the first control gate to the second control gate, wherein the first control gate includes a side wall, and the additional conductive contact includes a second portion adjacent the side wall of the first control gate.

13. The apparatus of claim 12, further comprising a dielectric pillar between the conductive contact and the additional conductive contact, the dielectric pillar extending in the direction from the first control gate to the second control gate.

14. The apparatus of claim 11, wherein the second control gate includes a first conductive material adjacent the conductive contact and a second conductive material adjacent the first conductive material.

15. The apparatus of claim 14, wherein the conductive contact includes third conductive material adjacent the first conductive material of the conductive contact, and a fourth conductive material adjacent the third conductive material.

16. The apparatus of claim 15, wherein:
at least one of the first conductive material and the third conductive material includes titanium nitride; and
at least one of the second conductive material and the fourth conductive material includes tungsten.

17. A method comprising:
forming levels of first dielectric materials and forming levels of second dielectric materials interleaved with the levels of first dielectric materials;
forming memory cells including forming a pillar associated with the memory cells through the levels of first dielectric materials and the levels of second dielectric materials;
forming a third material at a location in one of the levels of second dielectric materials;
replacing the levels of second dielectric materials with levels of conductive materials;
removing the third material from the location in one of the levels of second dielectric materials; and
forming a conductive contact including forming a portion of the conductive contact in the location in one of the levels of second dielectric materials.

18. The method of claim 17, further comprising:
forming a contact opening in the levels of first dielectric materials and the levels of second dielectric materials;
forming a dielectric liner in the contact opening, such that the dielectric liner includes a bottom positioned over the location in one of the levels of second dielectric materials, wherein the third material is formed after forming the dielectric liner.

19. The method of claim 18, further comprising:
removing a portion of the bottom of the dielectric liner, wherein the third material is formed after removing the portion of the bottom of the dielectric liner.

20. The method of claim 17, wherein forming the pillar associated with the memory cells includes:
forming a first opening through a first deck of materials;
forming a second deck of materials over the first deck of materials;
forming a second opening through the second deck of materials; and
forming the pillar at the first opening and the second opening.
